(19) United States
(12) Patent Application Publication
(10) Pub. No.: US 2024/0334700 A1
(43) Pub. Date: Oct. 3, 2024

(54) MICROELECTRONIC DEVICES INCLUDING VERTICAL PLANAR MEMORY CELL STRUCTURES, AND RELATED MEMORY DEVICES AND ELECTRONIC SYSTEMS

(71) Applicant: Micro Technology, Inc., Boise, ID (US)

(72) Inventor: Yoshiaki Fukuzumi, Tokyo (JP)

(21) Appl. No.: 18/424,709

(22) Filed: Jan. 26, 2024

Related U.S. Application Data
(60) Provisional application No. 63/492,290, filed on Mar. 27, 2023.

(51) Int. Cl. H10B 43/27; H10B 43/35

(52) U.S. Cl. CPC H10B 43/27; H10B 43/35

(57) ABSTRACT

A method of forming a microelectronic device includes forming a preliminary stack structure with tiers of sacrificial material and insulative material over a base structure, forming a slot with a first region and second regions vertically extending through the preliminary stack structure, forming memory cell material, mask material, and trim material within the slot, removing portions of the trim material within the first region of the slot, removing portions of the trim material, the mask material, and the memory cell material within the second regions of the slot structures to form memory string structures, and replacing the sacrificial material of the tiers of the preliminary stack structure with conductive material. The first region horizontally extends in a first direction. The second regions intersect the first region and horizontally extend in a second direction. The memory string structures are horizontally separated from one another in the second direction.

### CROSS-REFERENCE TO RELATED APPLICATION

This application claims the benefit under 35 U.S.C. § 119(e) of U.S. Provisional Patent Application Ser. No. 63/492,290, filed Mar. 27, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes strings of memory cells vertically extending through one or more stack structures including tiers of conductive material and insulative material. Each string of memory cells may include at least one select device coupled thereto. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Vertical memory array architectures generally include electrical connections between the conductive material of a tier of the stack structure(s) of the memory device and control logic devices (e.g., string drivers) so that the memory cells of the vertical memory array can be uniquely selected for writing, reading, or erasing operations.

Unfortunately, as feature packing densities have increased and margins for formation errors have decreased, conventional fabrication methods and resulting structural configurations have resulted in undesirable defects that can diminish desired memory device performance, reliability, and durability.

### BRIEF DESCRIPTION OF THE DRAWINGS

FIG. 1 is a simplified, partial top-down view of a microelectronic device structure at a processing stage of a method of forming a microelectronic device, in accordance with embodiments of the disclosure.

FIGS. 2A through 2Q are simplified, partial perspective cross-sectional views of a portion of the microelectronic device structure shown in FIG. 1 at different processing stages of the method of forming the microelectronic device.

FIG. 2R is a simplified, partial perspective cross-sectional view of an additional portion of the microelectronic device structure at the processing stage shown in FIG. 2Q.

FIG. 3 is a simplified, partial top-down view of the microelectronic device structure following the processing stage of FIGS. 2Q and 2R.

FIG. 4 is a simplified, partial top-down view of a microelectronic device structure, in accordance with additional embodiments of the disclosure.

FIG. 5 is a simplified, partial top-down view of a microelectronic device structure, in accordance with yet additional embodiments of the disclosure.

FIG. 6 is a simplified, partial top-down view of a microelectronic device structure, in accordance with further embodiments of the disclosure.

FIG. 7 is a simplified, partial top-down view of a microelectronic device structure, in accordance with yet further embodiments of the disclosure.

FIG. 8 is a simplified, partial top-down view of a microelectronic device structure, in accordance with yet still further embodiments of the disclosure.

FIG. 9 is a schematic block diagram illustrating an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. The description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one of the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “over,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Moreover, if a material is formed to cover a surface (e.g., a substantially vertical sidewall of a structure), the material may be referred to as being formed “over” the surface even though the material may not be spatially above the covered surface. Likewise, the surface may be referred to as being “under” the formed material. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, “sacrificial material” means and includes one material that may be selectively removed relative to one or more other materials (e.g., one or more insulative materials). The sacrificial material may be selectively etchable relative to the one or more other materials during common (e.g., collective, mutual) exposure to a first etchant; and the one or more other materials may be selectively etchable to the sacrificial material during common exposure to a second, different etchant. As used herein, a material is “selectively etchable” relative to another material if the material exhibits an etch rate that is at least about five times (5×) greater than the etch rate of another material, such as about ten times (10×) greater, about twenty times (20×) greater, or about forty times (40×) greater. By way of non-limiting example, depending on the material composition of the one or more other materials, the sacrificial material may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and at least one semiconductive material (e.g., polycrystalline silicon). The sacrificial material may, for example, be selectively etchable relative to the one or more other materials during common exposure to a wet etchant comprising phosphoric acid (H₃PO₄). In addition, a “sacrificial structure” means and includes a structure formed of and including sacrificial material.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

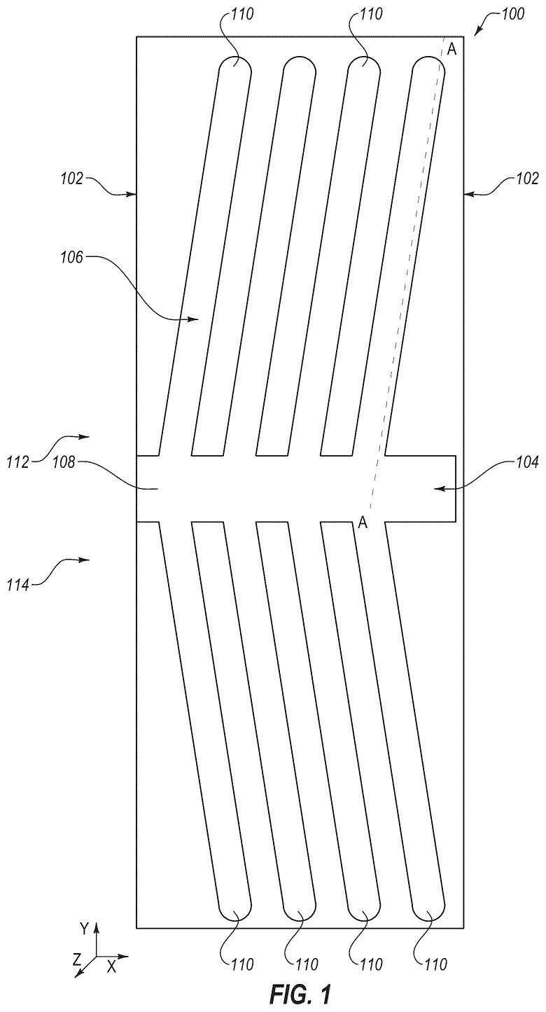

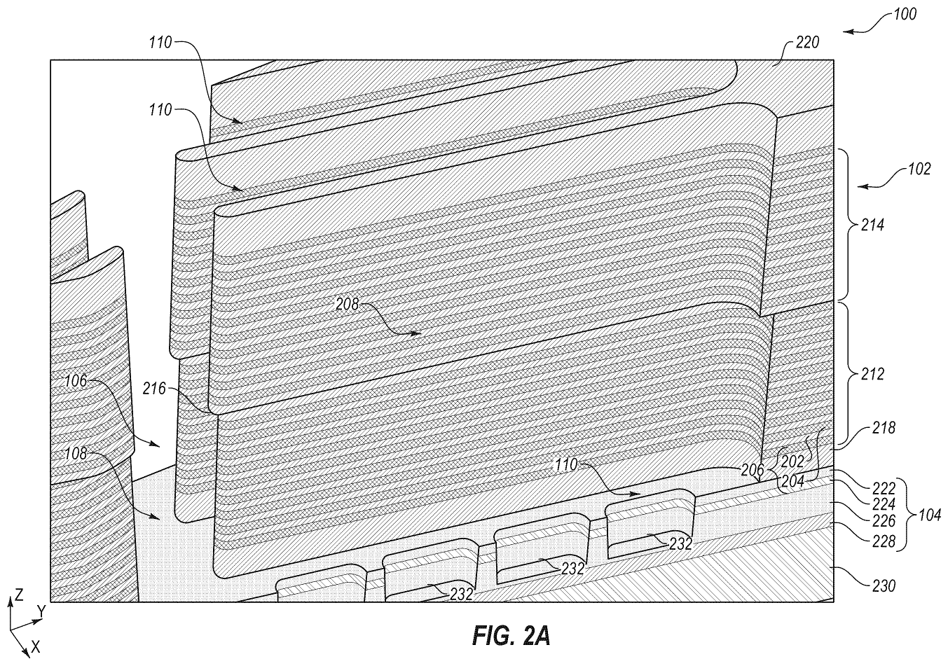

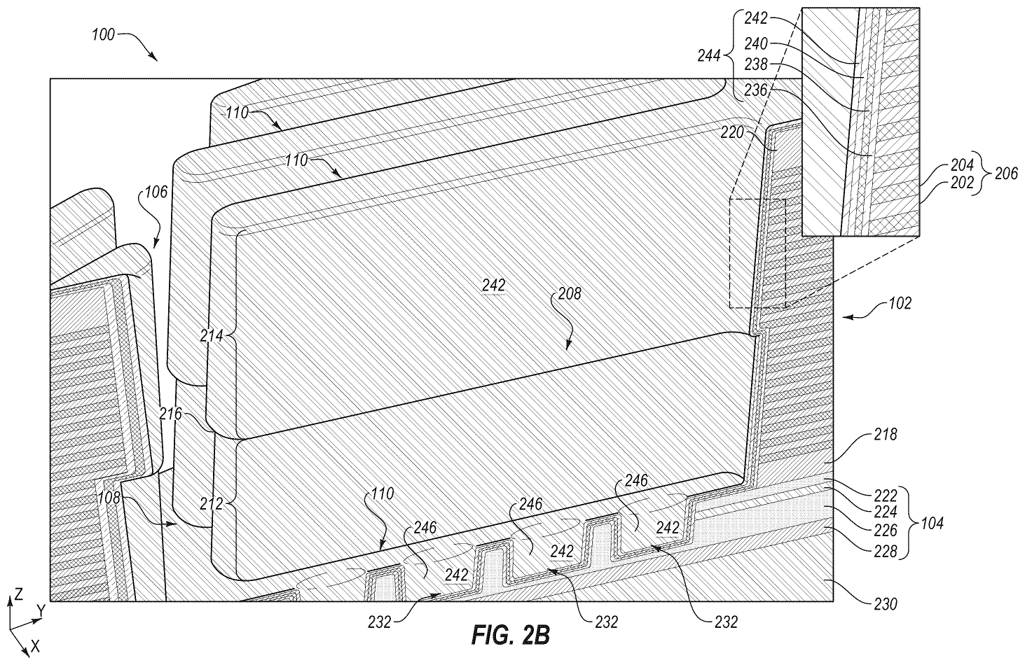

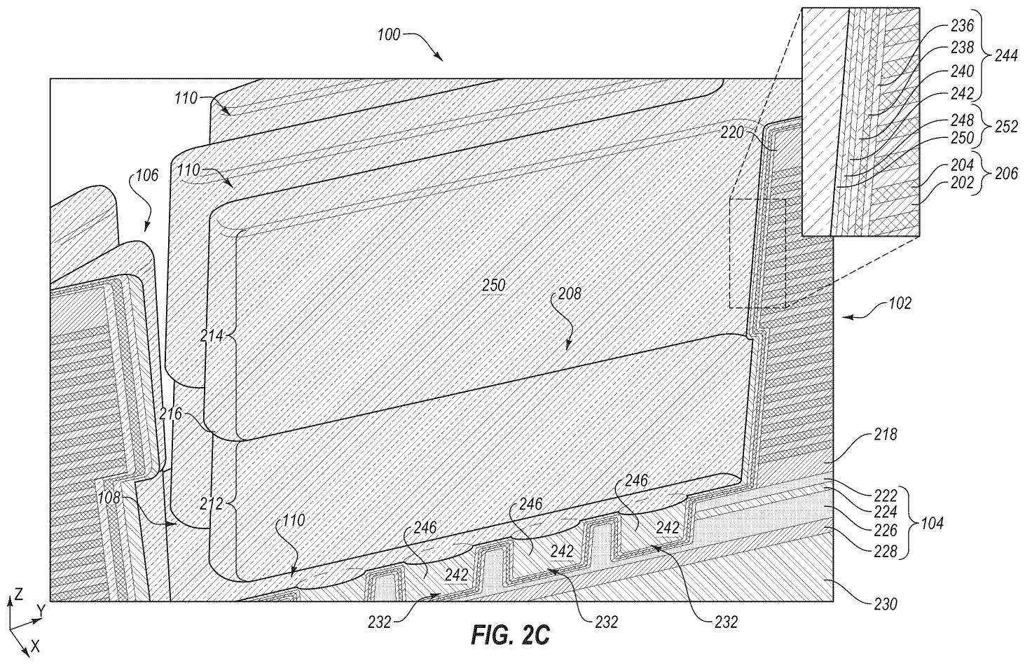

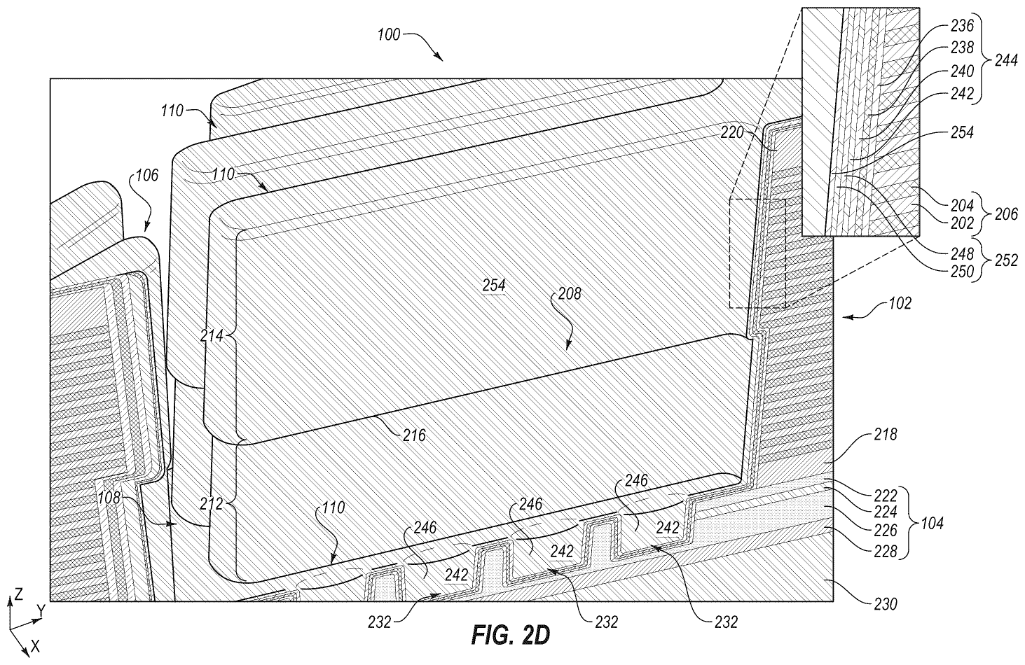

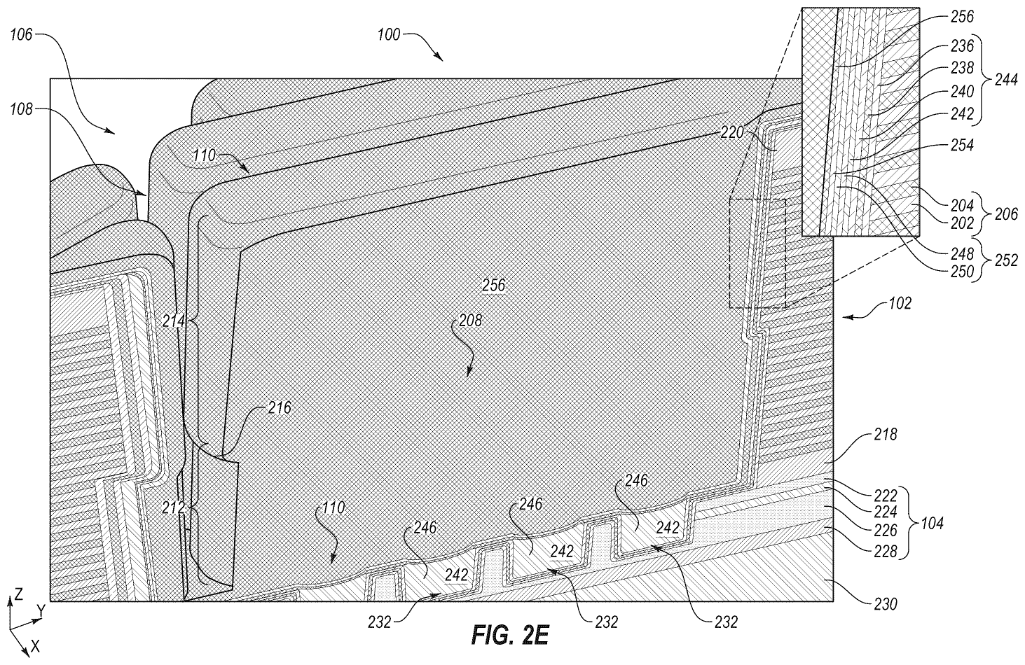

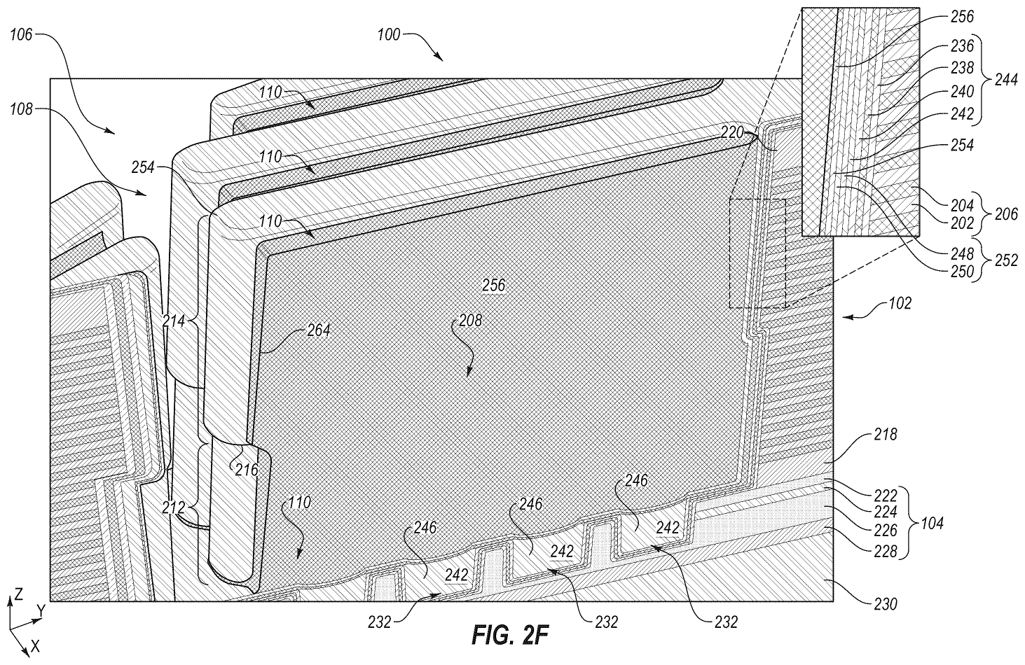

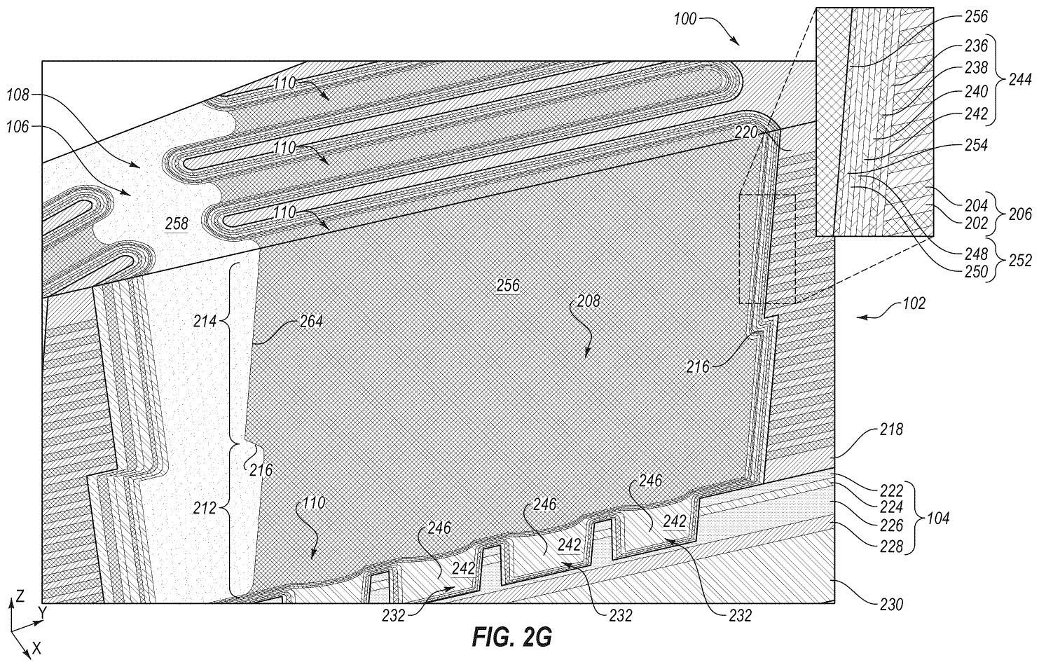

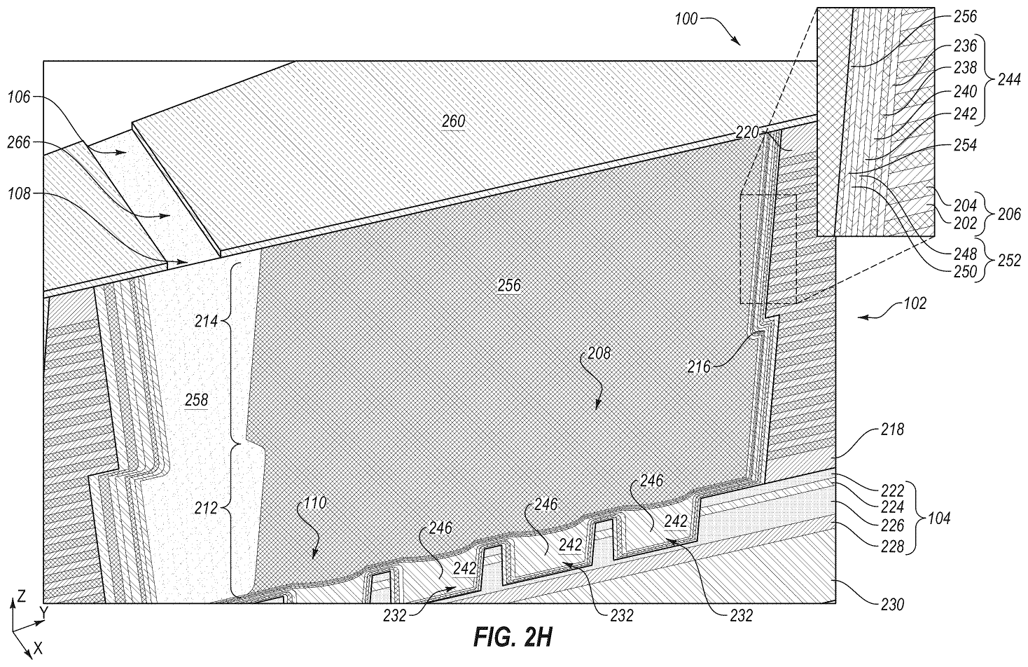

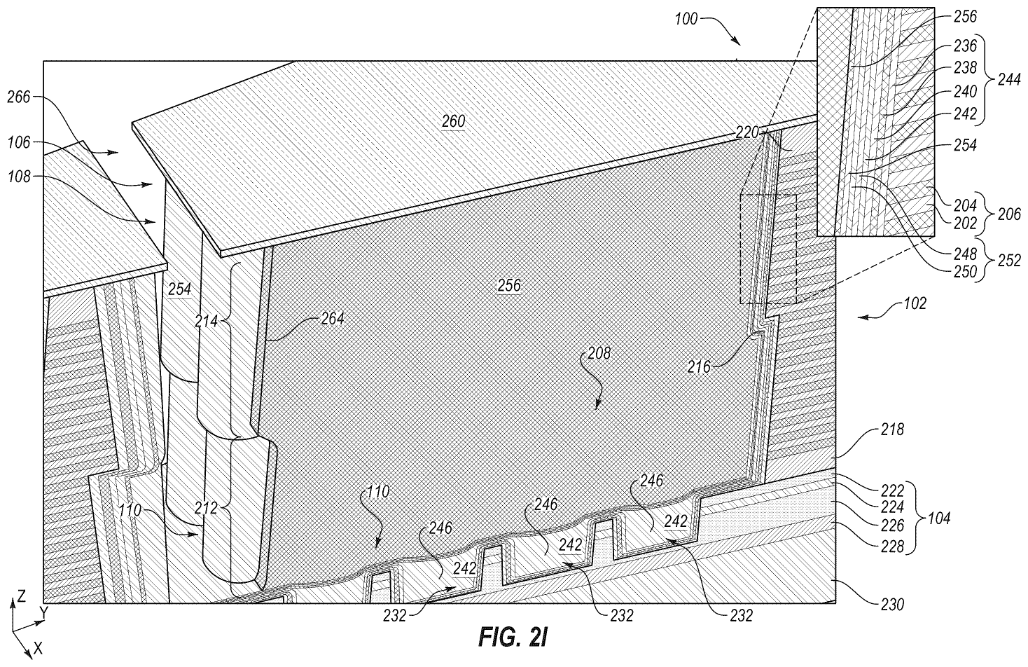

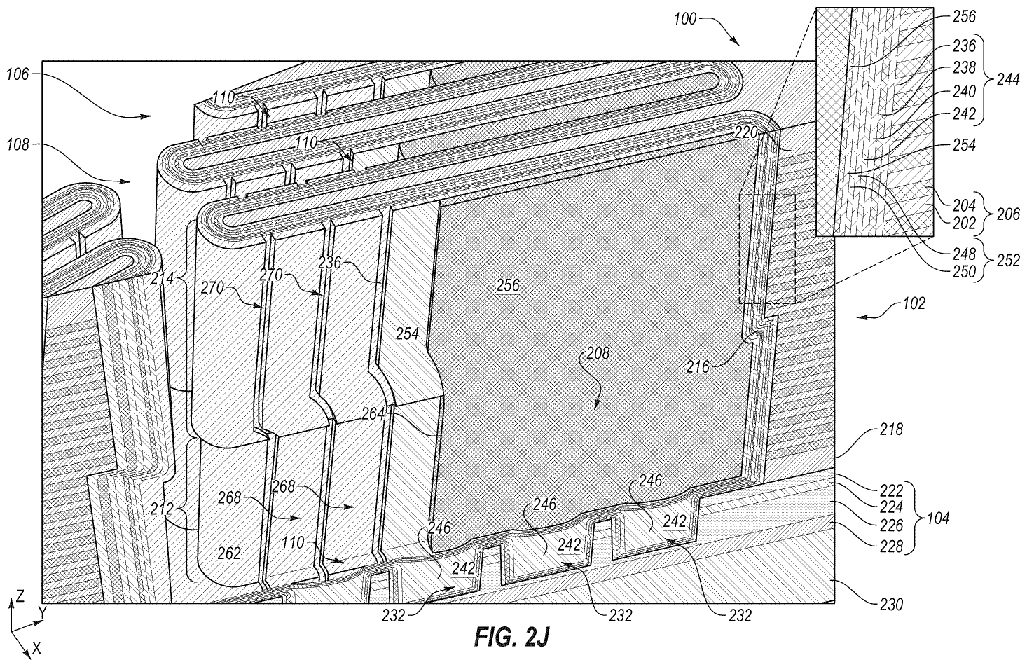

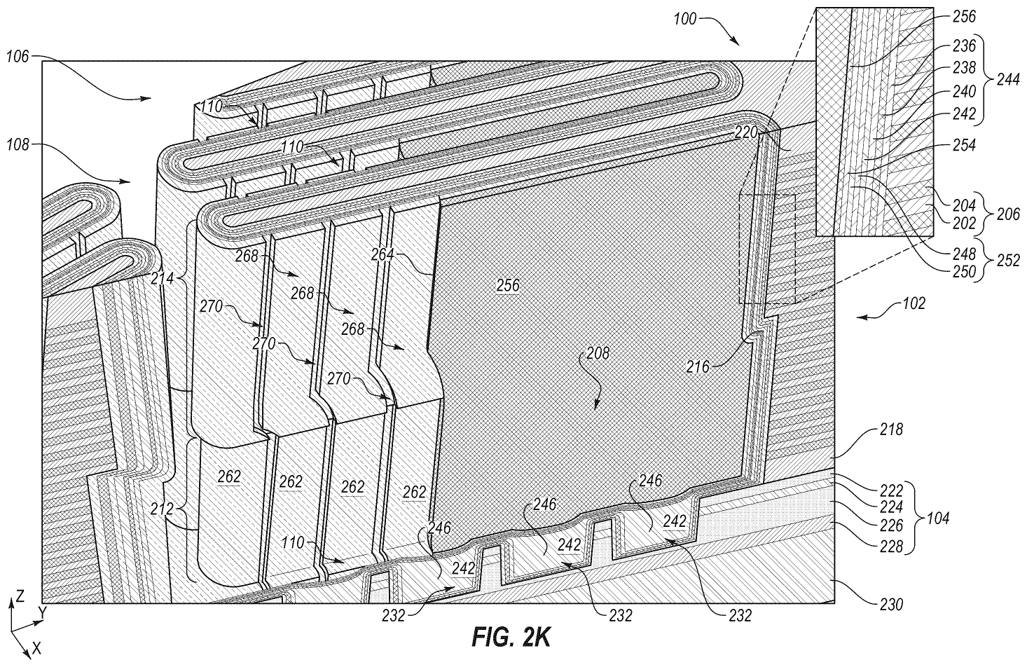

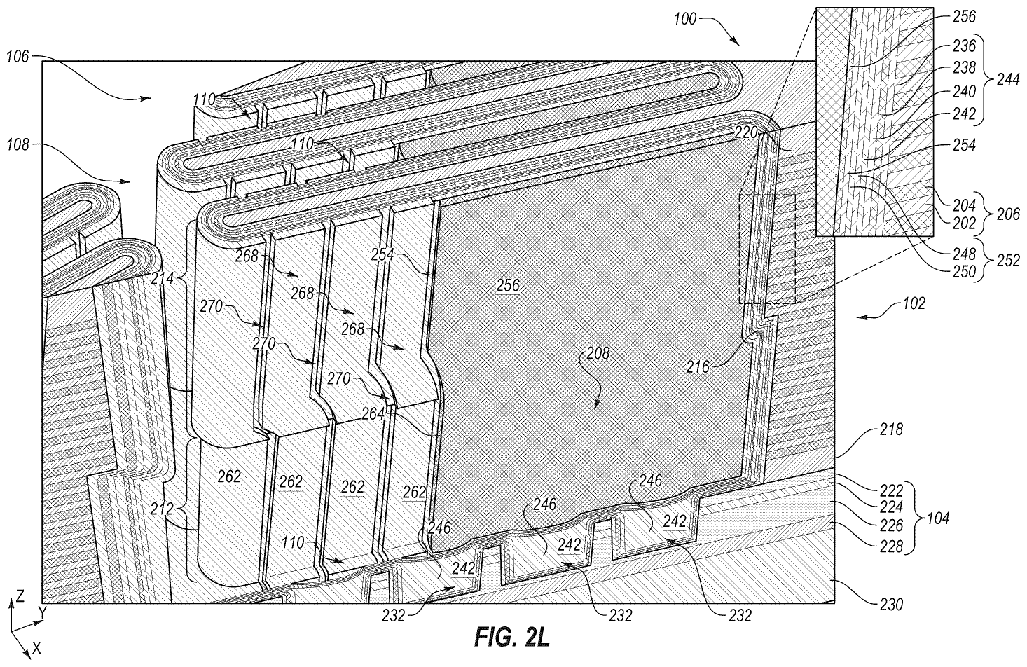

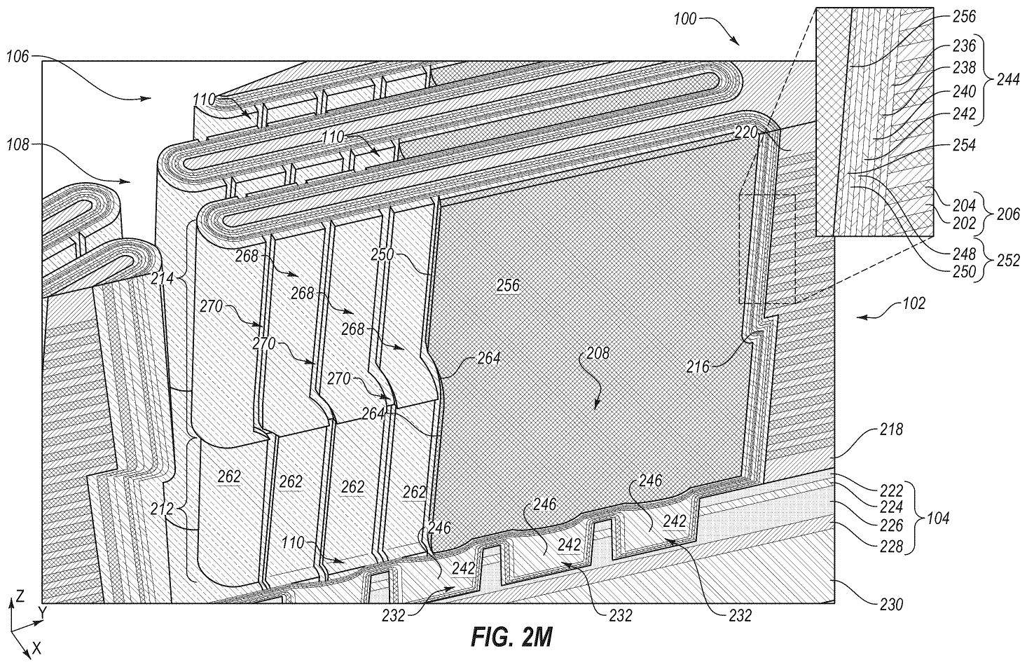

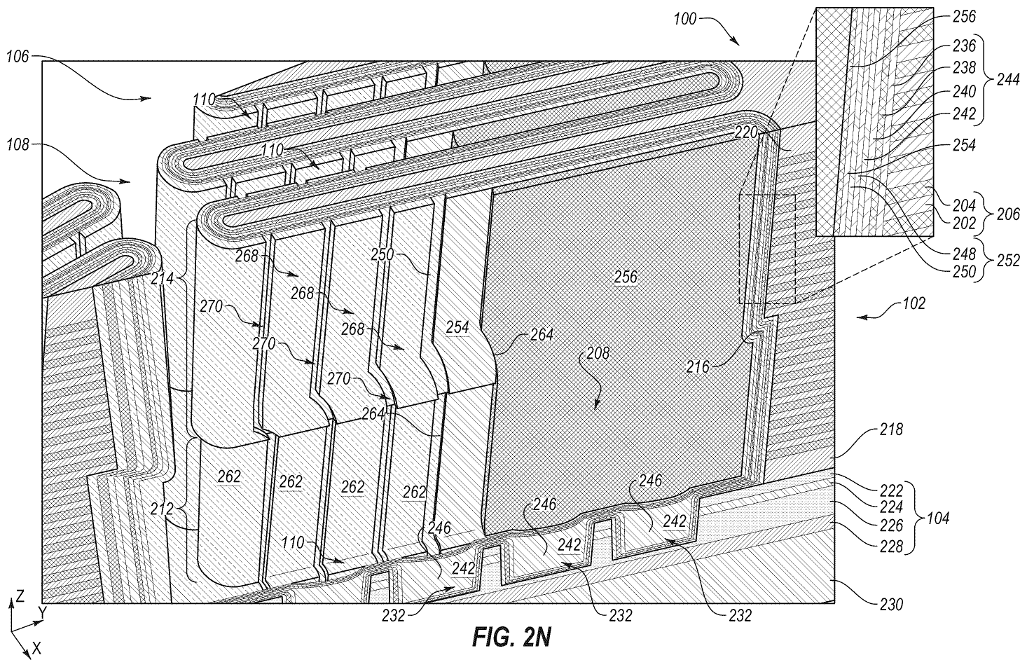

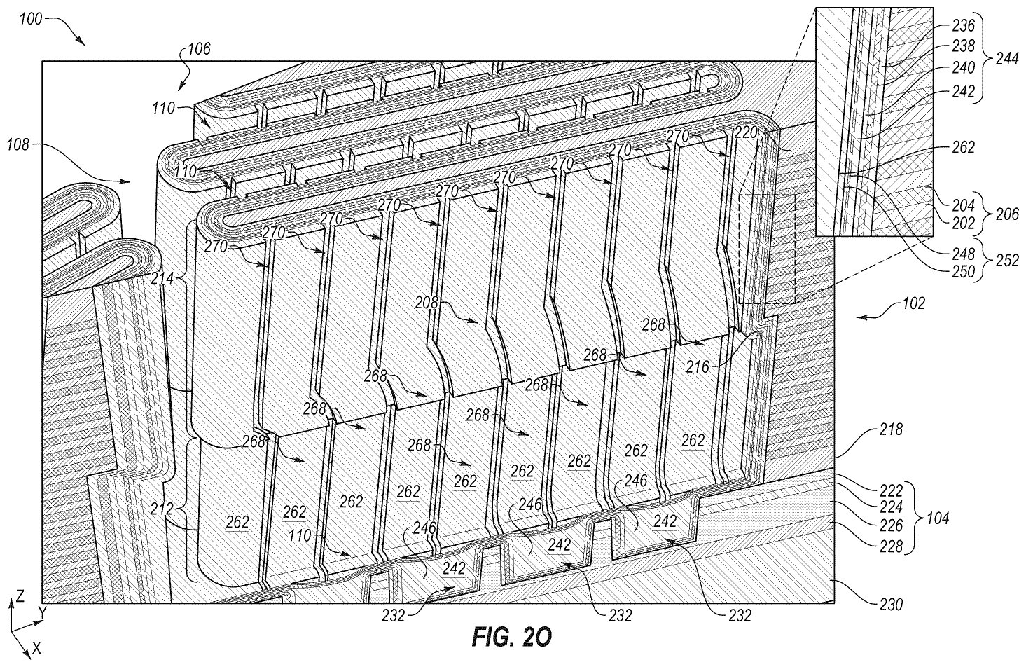

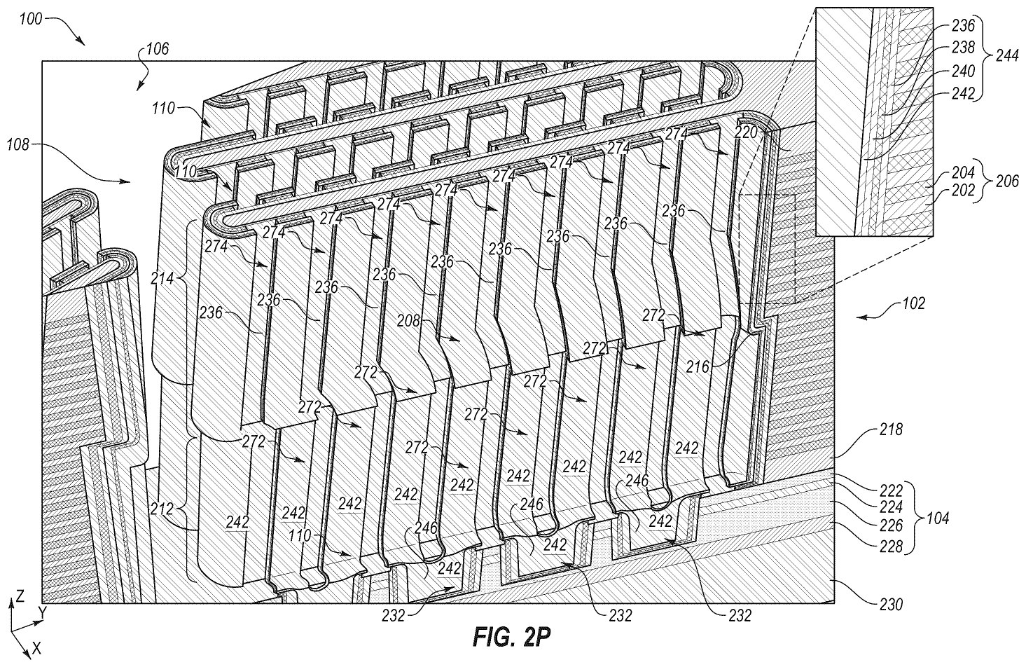

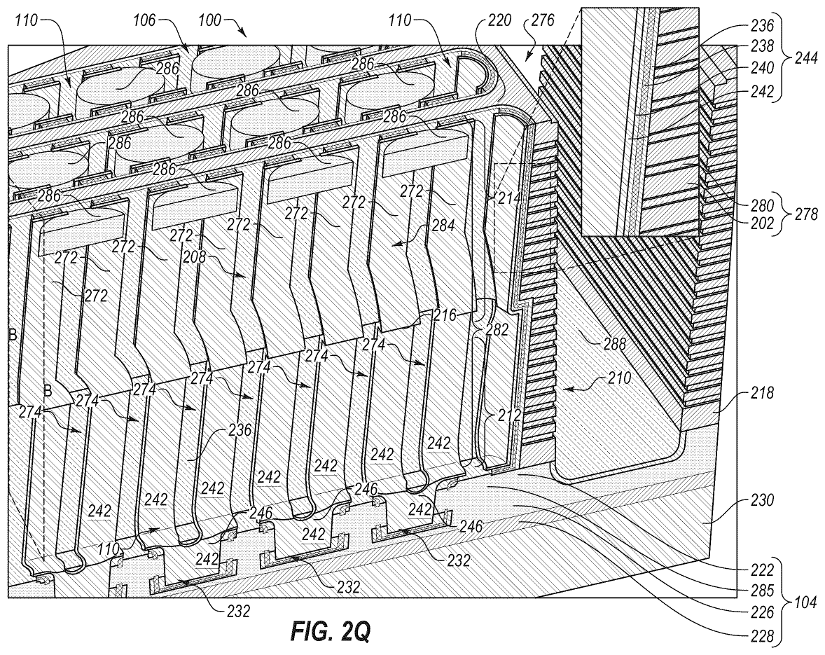

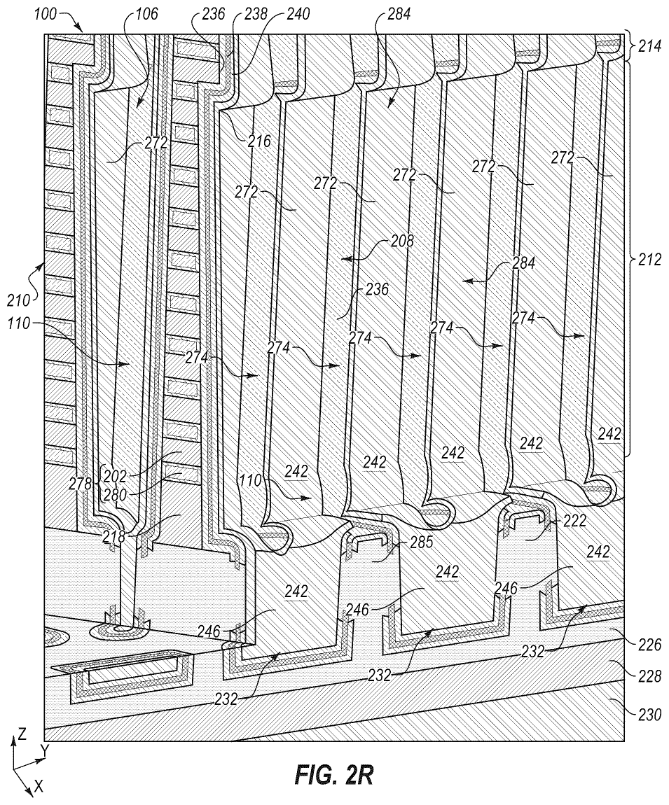

FIG. 1 and FIGS. 2A through 2R are various views (described in further detail below) illustrating a microelectronic device structure 100 at different processing stages of a method of forming a microelectronic device (e.g., a memory device, such as a 3D NAND Flash memory device), in accordance with embodiments of the disclosure. With the description provided below, it will be readily apparent to one of ordinary skill in the art that the structures (e.g., the microelectronic device structure 100) and devices (e.g., microelectronic devices) described herein may be employed in various relatively larger devices and/or systems. For clarity and ease of understanding the drawings and associated description, not all features (e.g., regions, structures, materials, devices) of the microelectronic device structure 100 depicted in one or more of FIG. 1 and FIGS. 2A through 2R are depicted in the one or more other of FIG. 1 and FIGS. 2A through 2R.

FIG. 1 depicts a simplified, partial top-down view of a microelectronic device structure 100 at a processing stage of a method of forming a microelectronic device, in accordance with embodiments of this disclosure. The microelectronic device structure 100 may be formed to include a preliminary stack structure 102 over a base structure 104. The microelectronic device structure 100 may include a profile slot 106 therein, the profile slot 106 defining a void in the preliminary stack structure 102. As depicted in FIG. 1, the profile slot 106 has a profile defined by a backbone region 108 (also referred to herein as a “first region”) and one or more rib regions 110 (also referred to herein as “second regions”) extending horizontally from the backbone region 108.

As shown in FIG. 1, the backbone region 108 may have a substantially rectangular profile formed by a part of the profile slot 106, the backbone region 108 including a relatively long edge (e.g., along the X-direction) and a relatively short edge (e.g., along the Y-direction substantially orthogonal to the X-direction). The rib regions 110 may be individually horizontally spaced from one another (e.g., in the X-direction) at between approximately one hundred nanometers (100 nm) to approximately one hundred and fifty nanometers (150 nm). Alternatively, the rib regions 110 may be individually spaced from one another at the pitch of (e.g., in the X-direction) approximately one hundred twenty-five nanometers (125 nm) to approximately one hundred seventy-five nanometers (175 nm). In one embodiment, the rib regions 110 are individually spaced from one another at the pitch of (e.g., in the X-direction) approximately one hundred forty-six nanometers (146 nm).

The rib regions 110 may include multiple, substantially linear portions of the profile slot 106 in the preliminary stack structure 102. Rib regions 110 may individually extend from opposing sides of the relatively long edges (e.g., extending in the X-direction) of the backbone region 108. An individual rib region 110 may include a relatively long edge (e.g., horizontal boundary) along a direction in which the rib regions 110 extends from the backbone region 108. Multiple rib regions 110 individually extending from each opposing side (e.g., along the X-direction) of the backbone region 108 may collectively form respective sets of rib regions 110 (e.g., first set of ribs 112, second set of ribs 114). The first set of ribs 112 and the second set of ribs 114 may form mirror images of each other, symmetrical across a lateral centerline (e.g., extending in the X-direction and centrally positioned in the Y-direction) of the backbone region 108. Alternatively, some of the rib regions 110 may individually form different angles with respect to the backbone region 108 compared to other of the rib regions 110. For example, in one embodiment, individual rib regions 110 of the first set of ribs 112 form a first angle relative to the backbone region 108; while individual rib regions 110 of the second set of ribs 114 form a different angle relative to the backbone region 108. Rib regions 110 may extend from the backbone region 108 at a variety of angles relative to the backbone region 108. In one embodiment, the rib regions 110 individually extend from the backbone region 108 at an angle of approximately eighty degrees (80°). In other embodiments, the rib regions 110 individually extend from the backbone region 108 at angles between approximately eighty-five degrees (85°) and approximately seventy-five degrees (75°). In other embodiments, the rib regions 110 individually extend from the backbone region 108 at angles of between approximately eighty degrees (80°) and approximately ninety degrees (90°), such as between approximately eighty-five degrees (85°) and approximately ninety degrees (90°). In other embodiments, the rib regions 110 individually extend from the backbone region 108 at angles of less than approximately eighty degrees (80°), such as less than seventy-five degrees (75°), such as less than seventy degrees (70°), such as less than sixty-five degrees (65°), such as less than sixty degrees (60°). The rib regions 110 may be spatially arranged relative to the backbone region 108 such that later-formed bit lines (e.g., data lines, digit lines) above (e.g., in the Z-direction) the preliminary stack structure 102 vertically overlie (e.g., in the Z-direction) later-formed corresponding vertical memory string structures within the profile of the rib regions 110, as will be described and shown in further detail below.

FIG. 2A is a simplified, partial perspective cross-sectional view of the portion of the microelectronic device structure 100 about a dashed line A-A depicted in FIG. 1 at the processing stage depicted in FIG. 1. As shown in FIG. 2A, the microelectronic device structure 100 may be formed to include the preliminary stack structure 102 including a vertically alternating (e.g., in a Z-direction) sequence of insulative material 202 and sacrificial material 204 arranged in tiers 206. The tiers 206 of the preliminary stack structure 102 may individually include the sacrificial material 204 vertically neighboring (e.g., directly vertically adjacent in the Z-direction) the insulative material 202.

The insulative material 202 of the individual tiers 206 of the preliminary stack structure 102 may be formed of and include at least one dielectric material, such one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the insulative material 202 of each of the tiers 206 of the preliminary stack structure 102 is formed of and includes a dielectric oxide material, such as SiOₓ (e.g., SiO₂). The insulative material 202 of each of the tiers 206 may be substantially homogeneous, or the insulative material 202 of one or more (e.g., each) of the tiers 206 may be heterogeneous.

The sacrificial material 204 of each of the tiers 206 of the preliminary stack structure 102 may be formed of and include at least one material (e.g., at least one insulative material) that may be selectively removed relative to the insulative material 202. The sacrificial material 204 may be selectively etchable relative to the insulative material 202 during common (e.g., collective, mutual) exposure to a first etchant; and the insulative material 202 may be selectively etchable to the sacrificial material 204 during common exposure to a second, different etchant. By way of non-limiting example, depending on the material composition of the insulative material 202, the sacrificial material 204 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and at least one semiconductive material (e.g., polycrystalline silicon). In some embodiments, the sacrificial material 204 of each of the tiers 206 of the preliminary stack structure 102 is formed of and includes a dielectric nitride material, such as SiN_{y} (e.g., Si₃N₄). The sacrificial material 204 may, for example, be selectively etchable relative to the insulative material 202 during common exposure to a wet etchant comprising phosphoric acid (H₃PO₄).

The preliminary stack structure 102 may be formed to include any desired number of the tiers 206. By way of non-limiting example, the preliminary stack structure 102 may be formed to include greater than or equal to sixteen (16) of the tiers 206, such as greater than or equal to thirty-two (32) of the tiers 206, greater than or equal to sixty-four (64) of the tiers 206, greater than or equal to one hundred and twenty-eight (128) of the tiers 206, or greater than or equal to two hundred and fifty-six (256) of the tiers 206.

The profile slot 106 may be defined as negative space within vertical boundaries of and at least partially defined by the preliminary stack structure 102. The preliminary stack structure 102 may include sidewalls 208 that define horizontal boundaries (e.g., in the X-direction, the Y-direction, or in horizontal directions that are a combination of the X- and Y-directions) of the profile slot 106. Each rib region 110 may be horizontally bounded by two opposing sidewalls 208 of the preliminary stack structure 102 that face each other. In other words, a pair of opposing sidewalls 208 may form two (2) relatively long horizontal boundaries of an individual rib region 110 of the profile slot 106.

The sidewalls 208 of the preliminary stack structure 102 may taper as a result of removal processes (e.g., deep dry etch operations) effectuated on the preliminary stack structure 102 to form the profile slot 106 therein. Alternatively, the sidewalls 208 may be formed to be substantially vertical. As used in the following description, the sidewalls 208 may include substantially vertical surfaces of the preliminary stack structure 102 and/or of other materials formed over the preliminary stack structure 102. Further, the sidewalls 208 may include substantially vertical surfaces of a later-formed stack structure 210 and/or of other materials formed over the later-formed stack structure 210.

The preliminary stack structure 102 may be formed to include one or more decks, each deck comprising multiple tiers 206. As depicted in FIG. 2A, the preliminary stack structure 102 may include a lower deck 212 and an upper deck 214 vertically overlying (e.g., in the Z-direction) the lower deck 212. The decks (e.g., lower deck 212, upper deck 214) of the preliminary stack structure 102 may individually include any desired number of tiers 206. By way of non-limiting example, the decks (e.g., lower deck 212, upper deck 214) of the preliminary stack structure 102 may individually include ten (10) tiers 206. Alternatively, the decks of the preliminary stack structure 102 may individually include fewer than ten (10) tiers 206. As further non-limiting examples, the decks of the preliminary stack structure 102 may individually include greater than or equal to eight (8) of the tiers 206, such as greater than or equal to sixteen (16) of the tiers 206, greater than or equal to thirty-two (32) of the tiers 206, greater than or equal to sixty-four (64) of the tiers 206, or greater than or equal to one hundred and twenty-eight (128) of the tiers 206.

As will be described in further detail below, the lower deck 212 and the upper deck 214 may be individually formed during different processing stages. As a result, the upper deck 214 may be partially horizontally (e.g., in the X- and/or Y-directions) offset (e.g., partially horizontally misaligned) with respect to the lower deck 212, thereby resulting in an upper deck overhang 216. A downward-facing lower (e.g., in the Z-direction) edge of the upper deck 214 of the preliminary stack structure 102 may be exposed by the partial horizontal misalignment between the upper deck 214 and the lower deck 212. Alternatively, a horizontal misalignment between the upper deck 214 and the lower deck 212 of the preliminary stack structure 102 may form a shoulder between the lower deck 212 and the upper deck 214. In such embodiments, an upward-facing upper (e.g., in the Z-direction) edge of the lower deck 212 of the preliminary stack structure 102 is exposed by the partial horizontal misalignment between the upper deck 214 and the lower deck 212. In some cases, a horizontal misalignment (e.g., in the X- and/or Y-directions) between the upper deck 214 and the lower deck 212 of the preliminary stack structure 102 may result in tapered sidewalls 208 of the preliminary stack structure 102. Such a tapered sidewall 208 may be positively sloped or may be a negatively sloped. In additional embodiments, the preliminary stack structure 102 exhibits substantially no horizontal offset, horizontal misalignment, and/or taper between the lower deck 212 and the upper deck 214.

As depicted in FIG. 2A, the microelectronic device structure 100 includes a bottom dielectric material 218 and a top dielectric material 220 at the bottom and top, respectively, of the preliminary stack structure 102. In particular, the top dielectric material 220 and the bottom dielectric material 218 may be respectively situated above and below (e.g., in the Z-direction) the tiers 206. The bottom dielectric material 218 and top dielectric material 220 may individually be formed of and include insulative material. The bottom dielectric material 218 and top dielectric material 220 may have substantially the same material composition as one another, or may have different material compositions than one another. The bottom dielectric material 218 and the top dielectric material 220 may individually be vertically thicker (e.g., in the Z-direction) than insulative material 202 of individual tiers 206 of the preliminary stack structure 102. In some embodiments, the top dielectric material 220 is vertically thicker (e.g., in the Z-direction) than the bottom dielectric material 218.

The microelectronic device structure 100 may further include a base structure 104, over which the preliminary stack structure 102 may be formed. The base structure 104 may include multiple materials. For example, the base structure 104 may include an upper base structure material 222, a middle base structure material 224, a lower base structure material 226, and a base structure dielectric material 228. The base structure 104 may be formed over a substrate 230. The upper base structure material 222 and the lower base structure material 226 may be formed of and include semiconductor material, such as doped semiconductor material (e.g., n-type polysilicon). The base structure dielectric material 228 may be formed of and include dielectric material. The middle base structure material 224 may be formed of additional semiconductor material, such as substantially undoped semiconductor material (e.g., undoped polysilicon). As depicted in FIG. 2A, the substrate 230 may comprise a structure or material upon which the base structure 104 is formed. In some embodiments, the substrate 230 comprises a semiconductor structure (e.g., a semiconductor wafer, such as a silicon wafer). In other embodiments, the substrate 230 includes at least one control logic region below (e.g., in the Z-direction) the base structure 104 including control logic devices configured to control various operations of other features (e.g., the vertical memory cells 284 depicted in FIG. 2Q) of the microelectronic device structure 100. As a non-limiting example, the control logic region of the substrate 230 may further include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control logic region of the substrate 230 may be coupled to a source structure, one or more access line routing structures, one or more select line routing structures, and/or one or more digit line structures. In some embodiments, the control logic region of the substrate 230 includes CMOS (complementary metal-oxide-semiconductor) circuitry. In such embodiments, the control logic region of the substrate 230 may be characterized as having a “CMOS under Array” (“CuA”) configuration.

As described above with respect to FIG. 1, the profile slot 106 may comprise a void space (e.g., trench, opening, slit) vertically extending through the preliminary stack structure 102. The profile slot 106 may extend vertically (e.g., in the Z-direction) through the top dielectric material 220, the tiers 206 of the upper deck 214 and of the lower deck 212, and the bottom dielectric material 218. A lower (e.g., in the Z-direction) boundary of the profile slot 106 may be at least partially defined by a top surface (e.g., an upper surface) of the base structure 104.

The base structure 104 may include multiple bottom plug cavities 232 therein. The bottom plug cavities 232 may comprise voids (e.g., openings, trenches, vias) vertically extending (e.g., in the Z-direction) partially through the base structure 104. In some embodiments, the bottom plug cavities 232 vertically extend through the upper base structure material 222 and middle base structure material 224, and partially through the lower base structure material 226. The bottom plug cavities 232 may be formed by removing material from the base structure 104. The bottom plug cavities 232 may individually exhibit a desired horizontal cross-sectional shape, such an elliptical horizontal cross-sectional shape.

Forming the microelectronic device structure 100 depicted in FIG. 2A may include forming the base structure 104 over the substrate 230. Forming the base structure 104 over the substrate 230 may include forming the base structure dielectric material 228 over the substrate 230; forming the lower base structure material 226 over the base structure dielectric material 228; forming the middle base structure material 224 over the lower base structure material 226; and forming the upper base structure material 222 over the middle base structure material 224.

Following formation of the base structure 104 over the substrate 230, the bottom plug cavities 232 may be formed by removing material from the upper base structure material 222, the middle base structure material 224, and the lower base structure material 226. The horizontal locations of the bottom plug cavities 232 may be selected to coincide with desired locations of later-formed vertical memory string structures, which may individually be formed above (e.g., in the Z-direction) bottom plugs subsequently formed within the bottom plug cavities 232.

Following formation of the bottom plug cavities 232, sacrificial material may be formed over the base structure 104, and may fill the bottom plug cavities 232. Portions of the sacrificial material overlying an uppermost surface (e.g., in the Z-direction) of the base structure 104 may then be removed (e.g., through an abrasive planarization process, such as a CMP process), which may leave the base structure 104 exposed and the bottom plug cavities 232 filled with sacrificial material to a vertical level (e.g., in the Z-direction) substantially coplanar with upper surfaces of the upper base structure material 222.

Following filling the bottom plug cavities 232 with sacrificial material, the lower deck 212 of the preliminary stack structure 102 may be formed over the base structure 104. The lower deck 212 of the preliminary stack structure 102 may be formed by forming the bottom dielectric material 218 over the base structure 104, followed by sequentially forming a vertically alternating sequence of the sacrificial material 204 and the insulative material 202.

Following formation of the lower deck 212 of the preliminary stack structure 102, a lower portion of the profile slot 106 (e.g., at the vertical extent, in the Z-direction, of the lower deck 212) may be formed by selectively removing material from the lower deck 212 of the preliminary stack structure 102, thereby forming a void having a horizontal profile (e.g., when viewed from a top-down perspective) of the backbone region 108 and rib regions 110.

Following formation of the lower portion of the profile slot 106, the lower portion of the profile slot 106 may be filled with sacrificial material. Portions of the formed sacrificial material overlying an uppermost surface (e.g., in the Z-direction) of the lower deck 212 may then be removed (e.g., through an abrasive planarization process, such as a CMP process).

Following filling the lower portion of the profile slot 106 with sacrificial material, the upper deck 214 of the preliminary stack structure 102 may be formed over the lower deck 212 of the preliminary stack structure 102 and over the sacrificial material within the lower portion of the profile slot 106. The upper deck 214 of the preliminary stack structure 102 may be formed by forming a vertically alternating sequence of the insulative material 202 and the sacrificial material 204 over the lower deck 212 and over the sacrificial material within the lower portion of the profile slot 106. Thereafter, the top dielectric material 220 may be formed over the tiers 206 of the insulative material 202 and the sacrificial material 204.

Following formation of the upper deck 214 of the preliminary stack structure 102, the upper portion of the profile slot 106 (e.g., in the upper deck 214) may be formed by selectively removing material from the upper deck 214 of the preliminary stack structure 102, thereby forming a void having a horizontal profile (e.g., when viewed from a top-down perspective) of the backbone region 108 and rib regions 110.

Following formation of the upper portion of the profile slot 106, sacrificial material may be removed from the lower portion of the profile slot 106 and from the bottom plug cavities 232, thereby resulting in the profile slot 106 (including the backbone region 108 and the rib regions 110 thereof) and the bottom plug cavities 232.

Referring now to FIG. 2B, following formation of the profile slot 106 as depicted in FIG. 2A, a barrier oxide material 236 may be formed over exposed surfaces of the microelectronic device structure 100. The barrier oxide material 236 may continuously extend over surfaces of the microelectronic device structure 100 defining the profile slot 106 and the bottom plug cavities 232. As shown in FIG. 2B, the barrier oxide material 236 may substantially continuously extend across and cover the exposed surfaces (e.g., the sidewalls 208) of the preliminary stack structure 102 and the base structure 104. The barrier oxide material 236 may be formed of and include dielectric oxide material (e.g., silicon oxide).

Following formation of the barrier oxide material 236, a storage nitride material 238 may be formed over the barrier oxide material 236. The storage nitride material 238 may substantially cover and continuously extend across the barrier oxide material 236. The storage nitride material 238 may conform to a topography of an upper surface of the barrier oxide material 236. The storage nitride material 238 may be provided inside and outside of the profile slot 106 and the bottom plug cavities 232. The storage nitride material 238 may be formed of and include dielectric nitride material (e.g., silicon nitride).

Following formation of the storage nitride material 238, a band engineered tunnel oxide material 240 may be formed over the storage nitride material 238. The band engineered tunnel oxide material 240 may substantially cover and continuously extend across the storage nitride material 238. The band engineered tunnel oxide material 240 may conform to a topography of an upper surface of the storage nitride material 238. The band engineered tunnel oxide material 240 may be provided inside and outside of the profile slot 106 and the bottom plug cavities 232. The band engineered tunnel oxide material 240 may be formed of and include a dielectric oxide material (e.g., silicon oxide).

Following formation of the band engineered tunnel oxide material 240, a semiconductor material 242 may be formed over the band engineered tunnel oxide material 240. The semiconductor material 242 may substantially cover and continuously extend across the band engineered tunnel oxide material 240. The semiconductor material 242 may be provided inside and outside of the profile slot 106 and the bottom plug cavities 232. The semiconductor material 242 may substantially fill portions of the bottom plug cavities 232 remaining unfilled by the barrier oxide material 236, the storage nitride material 238, and the band engineered tunnel oxide material 240. The semiconductor material 242 may be doped or may be substantially undoped. In some embodiments, the semiconductor material 242 is formed of and includes polysilicon doped (e.g., lightly doped) with one or more conductivity-enhancing species, such as N-type polysilicon (e.g., polysilicon doped with one or more N-type conductivity enhancing species, such as one or more of arsenic, phosphorous, and antimony).

The formation of the semiconductor material 242 may comprise forming the semiconductor material 242 at a thickness substantially greater than a desired final thickness of the semiconductor material 242. Following formation of the semiconductor material 242, the semiconductor material 242 may be partially removed to result in a relatively thinner remaining portion of the semiconductor material 242 extending over the sidewalls 208 of the preliminary stack structure 102. In one example, the semiconductor material 242 is formed to have an initial thickness of approximately fifteen (15) nanometers (nm). After partial removal of the semiconductor material 242, a remaining of the semiconductor material 242 within vertical boundaries of the preliminary stack structure 102 may have a thickness within a range of from approximately three (3) nm to about seven (7) nm, such as approximately five (5) nm.

In the present disclosure, the barrier oxide material 236, the storage nitride material 238, the band engineered tunnel oxide material 240, and the semiconductor material 242 may collectively be referred to as a memory cell material 244.

As depicted in FIG. 2B, when forming the barrier oxide material 236, the storage nitride material 238, the band engineered tunnel oxide material 240, and the semiconductor material 242, the bottom plug cavities 232 may be sequentially lined with the barrier oxide material 236, the storage nitride material 238, and the band engineered tunnel oxide material 240, and then filled in with the semiconductor material 242 (e.g., by conformal deposition of semiconductor material). Filling the bottom plug cavities 232 with the semiconductor material 242 may effectuate the formation of the bottom plugs 246 within the bottom plug cavities 232.

Referring now to FIG. 2C, following formation of the semiconductor material 242, a liner nitride material 248 may be formed over the semiconductor material 242. The liner nitride material 248 may substantially cover and continuously extend across the semiconductor material 242. The liner nitride material 248 may conform to a topography of an upper surface of the semiconductor material 242. The liner nitride material 248 may be provided inside and outside of the profile slot 106, and may cover the bottom plugs 246. The liner nitride material 248 may be formed of and include a dielectric nitride material (e.g., silicon nitride). The liner nitride material 248 may be formed to have a thickness of less than or equal to approximately ten (10) nm, such as within a range of from approximately ten (10) nm to about one (1) nm, less than or equal to approximately five (5) nm, or less than or equal to approximately three (3) nm. The liner nitride material 248 may mitigate oxidation of the semiconductor material 242.

Following formation of the liner nitride material 248, a liner oxide material 250 may be formed over the liner nitride material 248. The liner oxide material 250 may substantially cover and continuously extend across the liner nitride material 248. The liner oxide material 250 may conform to a topography of an upper surface of the liner nitride material 248. The liner oxide material 250 may be provided inside and outside of the profile slot 106. The liner oxide material 250 may be formed of and include a dielectric oxide material (e.g., silicon oxide). The liner oxide material 250 may be formed to have a thickness of less than or equal to approximately ten (10) nm, such as within a range of from approximately ten (10) nm to about one (1) nm, less than or equal to approximately five (5) nm, or less than or equal to approximately three (3) nm.

In the present disclosure, the liner nitride material 248 and the liner oxide material 250 may collectively be referred to as a liner material 252.

Referring next to FIG. 2D, following formation of the liner oxide material 250, a mask material 254 may be formed over the liner oxide material 250. The mask material 254 may substantially cover and continuously extend across the liner oxide material 250. The mask material 254 may conform to a topography of an upper surface of the liner oxide material 250. The mask material 254 may be provided inside and outside of the profile slot 106. In some embodiments, the mask material 254 is formed of and includes semiconductor material, such as polysilicon. The mask material 254 may be doped or may be undoped. By way of non-limiting example, the mask material 254 may be formed of and include n-type doped polysilicon. The mask material 254 may be formed to have a thickness within a range of from approximately five (5) nm to approximately fifteen (15) nm, such as approximately ten (10) nm.

Referring to FIG. 2E, following formation of the mask material 254, a trim material 256 may be formed over the mask material 254. The trim material 256 may substantially cover and continuously extend across the mask material 254. The trim material 256 may conform to a topography of an upper surface of the mask material 254. The trim material 256 may be provided inside and outside of the profile slot 106. The trim material 256 may at least partially (e.g., substantially) fill unfilled portions of the rib regions 110 of the profile slot 106. In some embodiments, the trim material 256 substantially fills remaining (e.g., unfilled) portions of the rib regions 110 between horizontally opposing portions of the preliminary stack structure 102. The trim material 256 may at least partially (e.g., substantially) fill the rib regions 110 of the profile slot 106 at least to a vertical height (e.g., in the Z-direction) of the preliminary stack structure 102. As shown in FIG. 2E, a portion of the backbone region 108 of the profile slot 106 may remain substantially unfilled following the formation of the trim material 256. The trim material 256 may only partially fill portions of the backbone region 108 remaining following the formation of the mask material 254.

The trim material 256 may be formed of and include at least one material having different etch selectivity than subsequently formed materials (e.g., a sacrificial fill material, a cover material, a mask oxide material). In some embodiments, the trim material 256 is formed of and includes a dielectric nitride material (e.g., silicon nitride). In additional embodiments, the trim material 256 is formed of and includes a dielectric nitride material, and an additional material (also referred to herein as a core material) having a different material composition than the dielectric nitride material on or over the dielectric nitride material.

Referring next to FIG. 2F, following formation of the trim material 256, a portion of the trim material 256 may be removed (e.g., via a nitride trim operation) to form trim edges 264 at or proximate intersections of the backbone region 108 and the rib regions 110 of the profile slot 106. The trim material 256 may be substantially removed from the backbone region 108, while remaining in the rib regions 110. As shown if FIG. 2F, in some embodiments, portions of the trim material 256 within the rib regions 110 and proximate the backbone region 108 are removed, such that the trim edges 264 of the trim material 256 are positioned within horizontal boundaries of the rib regions 110. The trim edges 264 of the trim material 256 may be horizontally offset from the backbone region 108. In additional embodiments, the trim edges 264 of the trim material 256 are positioned at or relatively closer to the horizontal boundaries of the backbone region 108. The material removal process (e.g., wet etch process) may disrupt the continuity of the trim material 256 within the profile slot 106, such that portions of the trim material 256 within individual rib regions 110 are discrete from and discontinuous with one another. In addition, portions of the trim material 256 outside of the boundaries (e.g., upper vertical boundaries) of the profile slot 106 may also be removed. The material removal process may expose surfaces of the mask material 254 within the backbone region 108 and outside of the boundaries of the profile slot 106.

Referring next to FIG. 2G, after removing portions of the trim material 256 to form the trim edge 264 (FIG. 2F), a sacrificial fill material 258 may be formed (e.g., non-conformally deposited) within remaining (e.g., unfilled) portions of the profile slot 106. The sacrificial fill material 258 may substantially fill the backbone region 108 of the profile slot 106. The sacrificial fill material 258 may also partially extend into the ribs region 110 of the profile slot 106. The sacrificial fill material 258 may be formed of and include at least one material having an etch selectivity relative to the trim material 256 and the mask material 254. In some embodiments, the sacrificial fill material 258 is formed of and includes carbon-containing material.

The sacrificial fill material 258 may initially be non-conformally formed (e.g., non-conformally deposited) inside and outside of the profile slot 106. Thereafter, portions of the sacrificial fill material 258 outside of the profile slot 106 may be removed (e.g., by way of CMP) such that the remaining portion of the sacrificial fill material 258 is substantially confined within the profile slot 106. During the material removal process (e.g., CMP process), portions (e.g., in the Z-direction) of the barrier oxide material 236, the storage nitride material 238, the band engineered tunnel oxide material 240, the semiconductor material 242, the liner nitride material 248, the liner oxide material 250, the mask material 254, and the trim nitride material 256 overlying an upper vertical boundary of the profile slot 106 also be removed. In some embodiments, the material removal process also partially removes (e.g., vertically recesses) the top dielectric material 220. The material removal process may expose the top dielectric material 220, and may form a substantially planar upper horizontal surface defined by and including coplanar upper horizontal surfaces of the sacrificial fill material 258, the top dielectric material 220, the barrier oxide material 236, the storage nitride material 238, the band engineered tunnel oxide material 240, the semiconductor material 242, the liner nitride material 248, the liner oxide material 250, the mask material 254, and the trim material 256.

Referring next to FIG. 2H, following removal of the upper portions of the sacrificial fill material 258 outside of the profile slot 106 (FIG. 2G), a cover material 260 may be formed over (e.g., in the Z-direction) the sacrificial fill material 258, the top dielectric material 220, the barrier oxide material 236, the storage nitride material 238, the band engineered tunnel oxide material 240, the semiconductor material 242, the liner nitride material 248, the liner oxide material 250, the mask material 254, and the trim material 256. The cover material 260 may be formed on or over the substantially planar upper horizontal surface defined by and including the coplanar upper horizontal surfaces of the sacrificial fill material 258, the top dielectric material 220, the barrier oxide material 236, the storage nitride material 238, the band engineered tunnel oxide material 240, the semiconductor material 242, the liner nitride material 248, the liner oxide material 250, the mask material 254, and the trim material 256. The cover material 260 may have a substantially planar upper horizontal surface. The cover material 260 may be formed of and include a dielectric oxide material (e.g., silicon oxide). In some embodiment, the cover material 260 comprises silicon oxide (e.g., SiO₂) formed (e.g., via deposition) using tetraeythlorthosilicate (“TEOS”) as a silicon source.

Following formation of the cover material 260, a portion thereof within horizontal boundaries of the backbone region 108 may be removed (e.g., by an etching process). As shown in FIG. 2H, the removal of the portion of the cover material 260 may result in a cover material gap 266 (e.g., trench, opening) positioned within a horizontal area of backbone region 108 of the profile slot 106. The cover material gap 266 may have an elongate horizontal cross-sectional shape (e.g., a rectangular horizontal cross-sectional shape), and may at least partially expose the sacrificial fill material 258 within the backbone region 108.

The cover material gap 266 may have a horizontal span, defined as a distance between opposing long edges of the cover material gap 266 (e.g., in the Y-direction) that exposes at least some of an upper surface of the sacrificial fill material 258 without exposing the trim material 256. Further, the cover material gap 266 may not expose any of the top dielectric material 220, the barrier oxide material 236, the storage nitride material 238, the band engineered tunnel oxide material 240, the semiconductor material 242, the liner nitride material 248, the liner oxide material 250, and the mask material 254. In some embodiments, the cover material gap 266 only partially (e.g., less than completely) exposes the upper surface of the sacrificial fill material 258.

Referring to FIG. 2I, following formation of the cover material 260 and the cover material gap 266, the sacrificial fill material 258 may be removed (e.g., exhumed) from the profile slot 106. Removal of the sacrificial fill material 258 from the profile slot 106 may expose portions of the mask material 254 within the horizontal area of the backbone region 108. The removal of the sacrificial fill material 258 may also expose additional portions of the mask material 254 within portions of the rib regions 110 proximate the backbone region 108.

Following removal of the sacrificial fill material 258, the trim material 256 may be further horizontally recessed (e.g., trimmed), so as to reposition the trim edges 264 relatively farther away from the backbone region 108. Exposed portions of the trim material 256 may be removed (e.g., using hot phosphoric acid etching) such that resulting new horizontal positions of the trim edges 264 are horizontally outward (e.g., relative to the backbone region 108) of respective horizontal positions of the trim edges 264 at the processing stage previously described with reference to FIG. 2F.

FIGS. 2J through 2R comprise simplified, partial perspective views of the microelectronic device structure 100 at processing stages of the method of forming the microelectronic device following the processing stage previously described with reference to FIG. 2I. In this regard, in each of FIGS. 2J through 2R, the cover material 260 is not depicted for clarity and ease of understanding the drawings and associated description. However, it will be understood that the cover material 260, as well as the cover material gap 266 therein and defined thereby, is still present at the processing stages of FIGS. 2J through 2R.

Following removal of the sacrificial fill material 258, a series of trim-etch cycles are effectuated to successively form one or more preliminary vertical memory string structures 268 on the sidewalls 208 of the preliminary stack structure 102. Sequential processing acts of one such trim-etch cycle are depicted in FIGS. 2J through 2M. The preliminary vertical memory string structures 268 may be formed in the rib regions 110 of the profile slot 106. The completion of an individual trim-etch cycle may result in the formation of individual vertical memory string structures 268 on sidewalls 208 of individual rib regions 110 of the profile slot 106. After formation of a first group of the preliminary vertical memory string structures 268 within the rib regions 110 by way of a first trim-etch cycle, a second group of the preliminary vertical memory string structures 268 may be formed within the rib regions 110 by way of a second trim-etch cycle, a third group of the preliminary vertical memory string structures 268 may be formed within the rib regions 110 by way of a third trim-etch cycle, and so on, until the series of trim-etch cycles is completed. Within an individual rib region 110, each subsequent trim-etch cycle may form an individual vertical memory string structure 268 horizontally positioned relative farther away from the backbone region 108 than another individual vertical memory string structure 268 formed through a previous trim-etch cycle.

At the processing stage depicted in FIG. 2J, two (2) of the preliminary vertical memory string structures 268 have been formed on an individual sidewall 208 of the preliminary stack structure 102 partially defining an individual rib region 110. The two (2) of the preliminary vertical memory string structures 268, as well as two (2) other of the preliminary vertical memory string structures 268 opposing the two (2) of the preliminary vertical memory string structures 268 may result from two (2) previous trim-etch cycles effectuated before the onset of the trim-etch cycle described with reference to FIGS. 2J through 2M. Preliminary vertical memory string structures 268 horizontally neighboring one another (e.g., in a horizontal direction along the long edge of the corresponding rib region 110) may be separated from one another by preliminary vertical memory string structure spaces 270. The widths of an individual preliminary vertical memory string structures 268 and of an individual preliminary vertical memory string structure spaces 270 horizontally neighboring the individual preliminary vertical memory string structures 268 may be determined, in part, by a respective width of the trim material 256 removed during a respective trim-etch cycle, as described in further detail below.

Referring to FIG. 2J, an individual trim-etch cycle includes removing portions of the trim material 256 within the rib regions 110 of the profile slot 106 to expose portions of the mask material 254 in the rib regions 110. Some removed portions of the trim material 256 may be referred to herein as the “memory string portions” of the trim material 256, as corresponding to the later-formed preliminary vertical memory string structures 268 formed at the locations of the removed portions of the trim material 256. Some exposed portions of the mask material 254 may be referred to herein as the “memory string portions” of the mask material 254 that are positioned at locations of the later-formed preliminary vertical memory string structures 268.

The material removal process of FIG. 2J may relocate the trim edges 264 of the trim material 256 horizontally farther away from the backbone region 108 of the profile slot 106. The material removal process may remove a memory string portion of the trim material 256. The material removal process may include subjecting the trim edges 264 of the trim material 256 established during a previous trim-etch cycle to at least one etchant (e.g., hot phosphoric acid etchant). The etchant may be introduced to the trim edges 264 within the rib regions 110 of the profile slot 106 by way of the cover material gap 266 (FIG. 2I) in the cover material 260 (FIG. 2I) and the backbone region 108 of the profile slot 106. The cover material 260 may mitigate (e.g., minimize, prevent) the etchant from entering the rib regions 110 of the profile slot 106 from above (e.g., in the Z-direction). In this manner, the material removal process may be carried out to progressively remove portions (e.g., a memory string portion) of the trim material 256. The horizontal extent of the trim material 256 removed (e.g., trimmed back) within an individual rib region 110 may be controlled, as desired, by choosing an etchant composition according to predetermined etching rates, by choosing the duration of the material removal process, and/or by choosing other parameters of the material removal process.

By removing a memory string portion of the trim material 256, the trim edge 264 may be horizontally receded to a selected new horizontal position to impart a desired horizontal width (e.g., in the horizontal direction along the long edge of the corresponding rib region 110) of individual preliminary vertical memory string structures 268 to be formed through the trim-etch cycle. The horizontal width (e.g., in the horizontal direction along the long edge of the corresponding rib region 110) of the individual preliminary vertical memory string structures 268 may be within a range of from about 20 nm to about 150 nm, such as from about 50 nm to about 120 nm, from about 80 nm to about 100 nm, or from about 90 nm to about 100 nm.

As depicted in FIG. 2J, an individual rib region 110 may be bounded by two opposing sidewall 208 portions of the preliminary stack structure 102. Accordingly, within an individual rib region 110, an individual trim-etch cycle may form a pair of preliminary vertical memory string structures 268, horizontally opposing one another (e.g., in a horizontal direction perpendicular to the long edge of the corresponding rib region 110), on opposing sidewalls 208 within the rib region 110. For a preliminary stack structure 102 having a profile slot 106 that comprises multiple rib regions 110, each trim-etch cycle may result in the formation of two (2) preliminary vertical memory string structures 268 horizontally opposing one another (e.g., in the horizontal direction perpendicular to the long edge of the corresponding rib region 110) within each respective rib region 110 of the profile slot 106.

Referring to FIG. 2K, following removal of the memory string portions of the trim material 256 within the rib regions 110, the resulting exposed portions of the mask material 254 (FIG. 2J) within the rib regions 110 are transformed into a mask oxide material 262. In some embodiments, the mask oxide material 262 is formed of and includes a dielectric oxide material, such as silicon oxide (e.g., SiO₂). The mask oxide material 262 may be formed by converting exposed portions of the mask material 254 to oxide (e.g., by thermal or plasma oxidation). The mask oxide material 262 may be formed to span a horizontal width (e.g., in the horizontal direction along a long edge of the corresponding rib region 110) between an adjacent preliminary vertical memory string structure space 270 and the trim edge 264. Further, the mask oxide material 262 may continuously span substantially an entire vertical extent (e.g., in the Z-direction) of the sidewall 208 of the preliminary stack structure 102. The mask oxide material 262 may be formed to have a thickness within a range of from about 5 nm to about 15 nm, such as from about 8 nm to about 12 nm, or about 10 nm. The mask oxide material 262 may be employed as an inhibition material, which may inhibit (e.g., slow, restrain) later removal (e.g., via wet etching) of the mask material 254 as will be explained in further detail below with respect to FIG. 2P. Alternatively, another type of inhibition material, instead of the mask oxide material 262, may be formed from the exposed portions of the mask material 254. For example, an inhibition material may comprise one or more materials formed by gas-phase doping or silicidation of the mask material 254.

Referring next to FIG. 2L, following the formation of the mask oxide material 262, additional portions of the trim material 256 may be removed (e.g., via a wet etchant) to further horizontally recede the trim edges 264 away from the backbone region 108 of the profile slot 106. The additional material removal process may include subjecting the trim edges 264 of the trim material 256 established at the processing stage of FIG. 2J to at least one etchant (e.g., hot phosphoric acid etchant). The etchant may be introduced to the trim edges 264 within the rib regions 110 of the profile slot 106 by way of the cover material gap 266 (FIG. 2I) in the cover material 260 (FIG. 2I) and the backbone region 108 of the profile slot 106. The cover material 260 may mitigate or prevent the etchant from entering the rib regions 110 of the profile slot 106 from above (e.g., in the Z-direction).

The additional portions of the trim material 256 may be removed along a horizontal extent (e.g., in the horizontal direction along the long edge of the corresponding rib region 110) that corresponds to a desired width of individual later-formed preliminary vertical memory string structure spaces 270 interposed horizontally (e.g., in the horizontal direction along the long edge of the corresponding rib region 110) between the horizontally neighboring preliminary vertical memory string structures 268. The width of individual preliminary vertical memory string structure spaces 270 (e.g., in the horizontal direction along the long edge of the corresponding rib region 110) may be greater than zero (0) nm and less than or equal to about 25 nm, such as within a range of from about 5 nm and about 20 nm, from about 10 nm to about 20 nm, or about 15 nm. The additional portion of the trim material 256 may be removed along substantially the entire vertical extent (e.g., in the Z-direction) of the sidewall 208 of the preliminary stack structure 102.

As shown in FIG. 2L, the removal of the additional portions of the trim material 256 may expose (e.g., uncover) respective portions of the mask material 254 underlying the removed additional portions of the trim material 256.

Referring next to FIG. 2M, following removal of the additional portions of the trim material 256, the resulting exposed portions of the mask material 254 may be selectively removed (e.g., via a tetramethylammonium hydroxide (“TMAH”) wet etch operation) to expose respective portions of the liner oxide material 250. By removing the portions of the mask material 254, preliminary vertical memory string structure spaces 270 may be formed between the trim edges 264 formed at the processing stage of FIG. 2K the preliminary vertical memory string structures 268 most horizontally proximate (e.g., in the horizontal direction along the long edge of the corresponding rib region 110) thereto.

As shown in FIG. 2M, the trim-etch cycle described with reference to FIGS. 2J through 2M may result in the formation of preliminary vertical memory string structures 268 within individual rib regions 110 of the profile slot 106. Individual preliminary vertical memory string structures 268 may be bounded horizontally (e.g., in the horizontal direction along the long edge of the corresponding rib region 110) by neighboring preliminary vertical memory string structure spaces 270. The preliminary vertical memory string structure spaces 270 may individually horizontally extend from and between neighboring preliminary vertical memory string structures 268. The preliminary vertical memory string structures 268 may vertically (e.g., in the Z-direction) span substantially the entire height of the preliminary stack structure 102, encompassing a vertical span (e.g., in the Z-direction) of both the lower deck 212 and the upper deck 214 of the preliminary stack structure 102.

Following the completion of an individual trim-etch cycle, one or more additional trim-etch cycle may be effectuated to form additional preliminary vertical memory string structures 268 and additional preliminary vertical memory string structure spaces 270 within the rib regions 110 of the profile slot 106. As shown in FIG. 2N, a portion of the trim material 256 neighboring the previously removed portion of the trim material 256, as shown in FIG. 2J, may be removed through a material removal process similar to the that previously described with reference to FIG. 2J. Thereafter, additional processing acts similar to those previously described with reference to FIGS. 2K through 2M may be effectuated for the additional trim-etch cycle.

FIG. 2O depicts an outcome of multiple trim-etch cycles to form multiple preliminary vertical memory string structures 268 within the rib regions 110 of the profile slot 106. As shown in FIG. 2O, substantially the entire horizontal span (e.g., in the horizontal direction along the long edge of the corresponding rib region 110) of the trim material 256 within the rib regions 110 has been removed, and preliminary vertical memory string structures 268 and the preliminary vertical memory string structure spaces 270 collectively horizontally extend across the horizontal span previously occupied by the trim material 256 within the rib regions 110.

A quantity of preliminary vertical memory string structures 268 within a group of the preliminary vertical memory string structures 268 within an individual rib region 110 may be equal to two times (2×) a quantity of trim-etch cycles effectuated. The quantity of preliminary vertical memory string structures 268 within an individual rib region 110 of the profile slot 106 may be determined, in part, by horizontal width (e.g., in the horizontal direction along the long edge of the corresponding rib region 110) of the rib region 110, the horizontal width (e.g., in the horizontal direction along the long edge of the corresponding rib region 110) of the preliminary vertical memory string structures 268, and the horizontal widths (e.g., in the horizontal direction along the long edge of the corresponding rib region 110) of the preliminary vertical memory string structure spaces 270. The preliminary vertical memory string structures 268 may each have substantially the same horizontal width as one another, or one or more of the preliminary vertical memory string structures 268 may have a different horizontal width than one or more other of the preliminary vertical memory string structures 268. In addition, the preliminary vertical memory string structure spaces 270 may each have substantially the same horizontal width as one another, or one or more of the preliminary vertical memory string structure spaces 270 may have a different horizontal width than one or more other of the preliminary vertical memory string structure spaces 270. In some embodiments, an individual rib region 110 has a group of eight (8) of the preliminary vertical memory string structures 268 formed on each of the two (2) opposing sidewalls 208 of the preliminary stack structure 102 partially defining the rib region 110. In other embodiments, an individual rib region 110 has seven (7) or fewer preliminary vertical memory string structures 268 formed on each of the two opposing sidewalls 208 of the preliminary stack structure 102 partially defining the rib region 110. In other embodiments, an individual rib region 110 has nine (9) or more preliminary vertical memory string structures 268 formed on each of the two opposing sidewalls 208 of the preliminary stack structure 102 partially defining the rib region 110.

During individual processing stages of an individual trim-etch cycle, multiple rib regions 110 of the profile slot 106 may be synchronously (e.g., simultaneously) acted upon. By way of non-limiting example, if multiple rib regions 110 are to individually have a group of sixteen (16) vertical memory string structures formed therein (e.g., eight (8) vertical memory string structures per sidewall 208 defining the individual rib region 110) during an individual trim-etch cycle, two (2) opposing (e.g., in the horizontal direction perpendicular to the long edge of the corresponding rib region 110) preliminary vertical memory string structures 268 may be formed within each of the rib regions 110 of the profile slot 106. Eight (8) trim-etch cycles may be conducted in this manner, thereby forming sixteen (16) of the preliminary vertical memory string structures 268 within each of the rib regions 110.

Referring to collectively to FIGS. 2O and 2P, following completion of the series of trim-etch cycles, portions of the liner oxide material 250, the liner nitride material 248, the semiconductor material 242, the band engineered tunnel oxide material 240, and the storage nitride material 238 that overlap the preliminary vertical memory string structure spaces 270 may be removed through one or more additional material removal processes to form vertical memory string structures 272 (FIG. 2P) and vertical memory string structure spaces 274 (FIG. 2P). Such material removal processes to arrive at the configuration of the microelectronic device structure 100 depicted in FIG. 2P are described in further detail below.

Following completion of the series of trim-etch cycles, portions of the liner oxide material 250 that were exposed by the trim-etch cycles (e.g., as described with reference to FIG. 2M) may be removed (e.g., via a wet etch process). Removal of the portions of the liner oxide material 250 may be conducted through the preliminary vertical memory string structure spaces 270, thereby changing the depths (e.g., in the horizontal direction perpendicular to the long edge of the corresponding rib region 110) of the preliminary vertical memory string structure spaces 270. The removal process may expose underlying portions of the liner nitride material 248.

Following removal of the portions of the liner oxide material 250, exposed portions of the liner nitride material 248 may be removed through an additional material removal process (e.g., an additional wet etching act). Alternatively, the portions of the liner nitride material 248 may be removed along with removal of the portions of liner oxide material 250 (e.g., using a single processing act). Removal of the exposed portions of the liner nitride material 248 may be conducted through the preliminary vertical memory string structure spaces 270, thereby further changing the depths (e.g., in the horizontal direction perpendicular to the long edge of the corresponding rib region 110) of the preliminary vertical memory string structure spaces 270. The removal process may expose underlying portions of the semiconductor material 242.

Following removal of the portions of the liner nitride material 248 that overlap the preliminary vertical memory string structure space 270, exposed portions of the semiconductor material 242 may be removed through an additional material removal process (e.g., an additional wet etching act). Alternatively, the portions of the semiconductor material 242 may be removed along with removal of one or more of the liner nitride material 248 and the liner oxide material 250 (e.g., using a single processing act). Removal of the semiconductor material 242 may be conducted through the preliminary vertical memory string structure spaces 270, thereby further changing the depth (e.g., in the horizontal direction perpendicular to the long edge of the corresponding rib region 110) of the preliminary vertical memory string structure spaces 270.

Following removal of the portions of the semiconductor material 242 that overlap the preliminary vertical memory string structure space 270, portions of the band engineered tunnel oxide material 240 may be removed through an additional material removal process (e.g., an additional wet etching act). Alternatively, the portions of the band engineered tunnel oxide material 240 may be removed along with removal of one or more of the doped polysilicon material 242, the liner nitride material 248, and the liner oxide material 250 (e.g., using a single processing act). Removal of the band engineered tunnel oxide material 240 may be conducted through the preliminary vertical memory string structure spaces 270, thereby further changing the depth (e.g., in the horizontal direction perpendicular to the long edge of the corresponding rib region 110) of the preliminary vertical memory string structure spaces 270.

Following removal of the portions of band engineered tunnel oxide material 240 that overlap the preliminary vertical memory string structure space 270, portions of the storage nitride material 238 may be removed through an additional material removal process (e.g., an additional wet etching act). Alternatively, portions of the storage nitride material 238 may be removed along with removal of one or more of the band engineered tunnel oxide material 240, the semiconductor material 242, the liner nitride material 248, and the liner oxide material 250 (e.g., using a single processing act). Removal of the storage nitride material 238 may be conducted through the preliminary vertical memory string structure spaces 270, thereby further changing the depths (e.g., in the horizontal direction perpendicular to the long edge of the corresponding rib region 110) of the preliminary vertical memory string structure spaces 270.

Following removal of the portions of storage nitride material 238 that overlap the preliminary vertical memory string structure space 270, portions of the barrier oxide material 236 may be exposed by the preliminary vertical memory string structure spaces 270. The preliminary vertical memory string structure spaces 270 may have depths that extend (e.g., in the horizontal direction perpendicular to the long edge of the corresponding rib region 110) at least to the band engineered tunnel oxide material 240, such as at least to the storage nitride material 240, such as at least to the barrier oxide material 236.

Along with the removal of portions of the liner oxide material 250, the liner nitride material 248, the semiconductor material 242, the band engineered tunnel oxide material 240, and/or the storage nitride material 238 that overlap the preliminary vertical memory string structure spaces 270, portions of the mask oxide material 262 (FIG. 2O), the mask material 254 (FIG. 2J), the liner oxide material 250 (FIG. 2C), and the liner nitride material 248 (FIG. 2C) may be removed from the preliminary vertical memory string structures 268, thereby exposing the semiconductor material 242. During this removal process, the mask oxide material 262 may inhibit (e.g., delay, slow, restrain) removal of the mask oxide material 262 and materials under the mask oxide material 262 (e.g., mask material 254, liner oxide material 250, liner nitride material 248) that overlap the preliminary vertical memory string structures 268. As such, removal of the mask oxide material 262 and the materials under the mask oxide material 262 that overlap the preliminary vertical memory string structures 268 may be carried out at a slower removal rate than the removal rate for the liner oxide material 250, the liner nitride material 248, the semiconductor material 242, the band engineered tunnel oxide material 240, and/or the storage nitride material 238 that overlap the preliminary vertical memory string structure spaces 270.

As shown in FIG. 2P, as a result of the forgoing material removal processes described with collective reference to FIGS. 2O and 2P, the vertical memory string structures 272 may be formed from the preliminary vertical memory string structures 268 (FIG. 2O) and the vertical memory string structure spaces 274 may be formed from the preliminary vertical memory string structure spaces 270 (FIG. 2O).

A horizontal pitch between respective horizontal centers of neighboring individual vertical memory string structures 272 may be within a range of from about 20 nm to about 175 nm, such as from about 50 nm to about 130 nm, from about 70 nm to about 115 nm, or about 90 nm.

As a result of the material removal processes (e.g., wet etching processes) employed to form the vertical memory string structures 272 and the vertical memory string structure spaces 274, the vertical memory string structure spaces 274 may individually be relatively wider (e.g., in the horizontal direction along the long edge of the corresponding rib region 110) than respective preliminary vertical memory string structure spaces 270 (FIG. 2O). For example, a width of an individual vertical memory string structure space 274 (e.g., in the horizontal direction along the long edge of the corresponding rib region 110) may be within a range of from about 30 nm to about 80 nm, such as about 55 nm. In addition, the vertical memory string structures 272 may individually be relatively narrower (e.g., in the horizontal direction along the long edge of the corresponding rib region 110) than respective preliminary vertical memory string structures 268 (FIG. 2O). For example, a width of an individual vertical memory string structure 272 (e.g., in the horizontal direction along the long edge of the corresponding rib region 110) may be within a range of from about 20 nm to about 50 nm, such as about 35 nm.

FIGS. 2Q and 2R are partial, simplified perspective views of the microelectronic device structure 100 at processing stages following that previously described with reference to FIG. 2P. FIG. 2R is a simplified, partial perspective cross-sectional view of a portion B (depicted in FIG. 2Q using dashed lines) of the microelectronic device structure 100 at the processing stage depicted in FIG. 2Q.

Referring to FIG. 2Q, following formation of the vertical memory string structures 272 and the vertical memory string structure spaces 274, the cover material 260 (FIG. 2I) may be removed (e.g., by an etching process). The cover material 260 may be substantially completely removed from over (e.g., in the Z-direction) the top dielectric material 220, the barrier oxide material 236, the storage nitride material 238, the band engineered tunnel oxide material 240, and the semiconductor material 242.

Still referring to FIG. 2Q, top plugs 286 may be formed in contact with upper portions of the vertical memory string structures 272. The top plugs 286 may be formed before forming semiconductor material 285 in the recesses in the base structure 104 as described below. The top plugs 286 may be formed by conventional photolithography techniques to pattern corresponding cavities for the top plugs 286, followed by forming semiconductor material within the top plug cavities. In some embodiments, the top plugs 286 are formed of and include polysilicon doped (e.g., lightly doped) with one or more conductivity enhancing species, such as N-type polysilicon (e.g., polysilicon doped with one or more N-type conductivity-enhancing species, such as one or more of arsenic, phosphorous, and antimony). As shown in FIG. 2Q, an individual top plug 286 may contact (e.g., physically contact, electrically contact) multiple (e.g., a plurality of) horizontally neighboring vertical memory string structures 272. In some embodiments, an individual top plug 286 contacts four (4) vertical memory string structures 272 within an individual rib region 110 of the profile slot 106. The top plugs 286 may be employed as drain side contact structures for the vertical memory string structures 272.

Following formation of the top plugs 286, at least one trench 276 (e.g., slot, slit, opening) may be formed to vertically extend completely through in the preliminary stack structure 102. The trench 276 may be formed by removing portions of the preliminary stack structure 102 (including the tiers 206 of insulative material 202 and sacrificial material 204 thereof). The trench 276 may be horizontally offset from the profile slot 106 (e.g., in the Y-direction), and may horizontally extend substantially parallel to the backbone region 108 of the profile slot 106. The trench 276 may have an elongate horizontal cross-sectional shapes (e.g., including a dimension in the X-direction larger than a dimension in the Y-direction). Additionally, the trench 276 may further vertically extend (e.g., in the Z-direction) through at least part of the upper base structure material 222 and the middle base structure material 224 of the base structure 104. In some embodiments, the trench 276 vertically extends downward (e.g., in the Z-direction) through the lower base structure material 226. In some embodiments, the trench 276 individually vertically extends downward to or beyond the base structure dielectric material 228.

Following formation of the trench 276, at least a portion of the middle base structure material 224 (FIG. 2P) of the base structure 104 may be removed (e.g., exhumed) to form a recess that extends horizontally (e.g., in the Y-direction) from the trench 276 to the bottom plugs 246 (FIG. 2P). Thereafter, portions of the barrier oxide material 236, the storage nitride material 238, and the band engineered tunnel oxide material 240 at the vertical elevation of the recess and horizontally surrounding the semiconductor material 242 of the bottom plugs 246 may be removed to expose the semiconductor material 242. As shown in FIG. 2Q, individual bottom plugs 246 may contact (e.g., physically contact, electrically contact) multiple (e.g., a plurality of) horizontally neighboring vertical memory string structures 272. In some embodiments, an individual bottom plug 246 contacts four (4) vertical memory string structures 272 within an individual rib region 110 of the profile slot 106. The bottom plugs 246 may be employed as source contact structures of the vertical memory string structures 272.

After exposing the bottom plugs 246, the recesses in the base structure 104 may be back-filled with semiconductor material 285 by way of the trench 276. The semiconductor material 285 may contact the semiconductor material 242 of the bottom plugs 246. The semiconductor material 285 may have substantially the same material composition as the semiconductor material 242, or may have a different material composition than the semiconductor material 242. In some embodiments, the semiconductor material 285 is formed of and includes doped polysilicon, such as n-type polysilicon (e.g., polysilicon doped with one or more n-type conductivity enhancing species, such as one or more of arsenic, phosphorous, and antimony).

Following the formation of the semiconductor material 285, portions of the semiconductor material 285 within the trench 276 may be removed (e.g., by isotropic etching), and a trench oxide material 288 may be formed at the bottom portion of the trench 276. The trench oxide material 288 may cover surfaces of the base structure 104 exposed at the bottom of the trench 276. For example, the trench oxide material 288 may be formed on or over surfaces of the upper base structure material 222, the semiconductor material 285, and the lower base structure material 226.

Following the formation of the top plugs 286, the trench oxide material 288, and the contact between the bottom plugs 246 and the semiconductor material 285, the microelectronic device structure 100 may be subjected to replacement gate processing. The replacement gate processing may at least partially (e.g., substantially) replace the sacrificial material 204 of the tiers 206 of the preliminary stack structure 102 with conductive material 280. By so doing, the replacement gate processing may convert the preliminary stack structure 102 into a stack structure 210. The stack structure 210 may include a vertically alternating (e.g., in the Z-direction) sequence of the insulative material 202 and the conductive material 280 arranged in tiers 278. During the replacement gate processing, the trench oxide material 288 may protect portions of the base structure 104 within a horizontal area of the trench 276 from removal.

The conductive material 280 of the tiers 278 of the stack structure 210 may be formed of and include one or more of at least one metal, at least one alloy, at least one conductive metal-containing material (e.g., at least one conductive metal nitride, at least one conductive metal silicide, at least one conductive metal carbide, at least one conductive metal oxide), and at least one conductively doped semiconductor material (e.g., conductively doped polysilicon). In some embodiments, the conductive material 280 is formed of and includes W. Optionally, at least one liner material (e.g., at least one insulative liner material, at least one conductive liner materials) may be formed around the conductive material 280. The liner material may, for example, be formed of and include one or more a metal (e.g., titanium, tantalum), an alloy, a metal nitride (e.g., tungsten nitride, titanium nitride, tantalum nitride), and a metal oxide (e.g., aluminum oxide). In some embodiments, the liner material comprises at least one conductive material employed as a seed material for the formation of the conductive material 280. In some embodiments, the liner material comprises titanium nitride (TiNₓ, such as TiN). In further embodiments, the replacement gate processing further includes forming a dielectric liner, such as deposition of aluminum oxide (AlOₓ, such as Al₂O₃). As a non-limiting example, for each of the tiers 278 of the stack structure 210, AlOₓ (e.g., Al₂O₃) may be formed directly adjacent the insulative material 202, TiNₓ (e.g., TiN) may be formed directly adjacent the AlOₓ, and W may be formed directly adjacent the TiNₓ. For clarity and ease of understanding the description, the liner material is not illustrated in FIGS. 2Q and 2R, but it will be understood that the liner material may be disposed around the conductive material 280.

With collective reference to FIGS. 2P and 2Q, the replacement gate processing employed to form the stack structure 210 may include treating the microelectronic device structure 100 with at least one wet etchant formulated to selectively remove portions of the sacrificial material 204 of the tiers 206 of the preliminary stack structure 102 through the trench 276. The wet etchant may be selected to remove the portions of the sacrificial material 204 without substantially removing portions of the insulative material 202 of the tiers 206 of the preliminary stack structure 102, and without substantially removing portions of the barrier oxide material 236, the liner oxide material 250, the cover material 260 (FIG. 2I), and the trench oxide material 288. In some embodiments wherein the sacrificial material 204 comprises a dielectric nitride material (e.g., SiN_{y}, such as Si₃N₄) and the insulative material 202 comprises a dielectric oxide material (e.g., SiOₓ, such as SiO₂), the sacrificial material 204 of the tiers 206 of the preliminary stack structure 102 may be selectively removed using a wet etchant comprising H₃PO₄. Following the selective removal of the portions of the sacrificial material 204, the resulting recesses may be filled with the conductive material 280 to form the stack structure 210 (including the tiers 278 thereof). Thereafter, the conductive material 280 may be isotropically recessed to provide electrical separation between the tiers 278. Following the formation of the stack structure 210, the trench 276 may be filled with dielectric material, thereby forming a filled trench structure (as described in further detail below with reference to FIG. 3).

In one alternative embodiment, the preliminary stack structure 102 is initially formed with a vertically alternating (e.g., in the Z-direction) sequence of the insulative material 202 and the conductive material 280 arranged in tiers 278, rather than the sequence of insulative material 202 and sacrificial material 204 arranged in tiers 206 as described above. The tiers 278 of the preliminary stack structure 102 may individually include the conductive material 280 vertically neighboring (e.g., directly vertically adjacent in the Z-direction) the insulative material 202. In such an embodiment, no replacement gate processing is subsequently employed.

Referring to FIG. 2Q, the tiers 278 of alternating insulative materials 202 and conductive materials 280 vertically overlie the bottom plugs 246. The stack structure 210 includes a vertical memory string region 282, which includes vertical memory cells 284 located at intersections of the vertical memory string structures 272 and conductive materials 280 of the tiers 278. Some of the conductive materials 280 may by employed as access line structures (e.g., word line structures) for the vertical memory cells 284. One or more of the tiers 278 proximal (e.g., in the Z-direction) to the bottom plugs 246 may be employed as select gate source (SGS) structure(s) and one or more of the tiers 278 proximal (e.g., in the Z-direction) to the top plugs 286 may be employed a select gate drain (SGD) structure(s).

Thus, in accordance with embodiments of the disclosure, a method of forming a microelectronic device includes forming a preliminary stack structure with tiers over a base structure, each tier of the preliminary stack structure including a sacrificial material and an insulative material vertically neighboring the sacrificial material, forming a slot with a first region and second regions vertically extending through the preliminary stack structure, forming memory cell material within the slot, forming mask material within the slot and over the memory cell material, forming trim material within the slot and over the mask material, removing portions of the trim material within the first region of the slot, removing portions of the trim material, the mask material, and the memory cell material within the second regions of the slot structures to form memory string structures, and replacing the sacrificial material of the tiers of the preliminary stack structure with conductive material after forming the memory string structures. The first region horizontally extends in a first direction. The second regions intersect the first region and horizontally extend in at least one second direction angled relative to the first direction. The memory string structures vertically extend through the preliminary stack structure and are horizontally separated from one another in the at least second direction.

In accordance with other embodiments of the disclosure, a microelectronic device includes a stack structure and a base structure vertically underlying the stack structure. The stack structure has tiers, each tier including conductive material vertically neighboring insulative material. The stack structure is divided into blocks horizontally extending in parallel in a first direction. The blocks are separated from one another in a second direction by insulative slot structures. The second direction is orthogonal to the first direction. At least one of the blocks has a slot, vertically extending through all of the tiers, and memory string structures. The slot includes a first region and second regions intersecting the first region. The first region horizontally extends in the first direction. The second regions horizontally extend in at least one third direction. The third direction is angled relative to the first direction and the second direction. The memory string structures vertically extend through the stack structure within horizontal areas of the second regions of the slot. The memory string structures are horizontally separated from one another in the at least one third direction. The base structure includes plug structures and additional conductive material. The plug structures are within the horizontal areas of the second regions of the slot of the at least one of the blocks. The plug structures contact the memory string structures of the at least one of the blocks. The additional conductive material contact side surfaces of the plug structures.

In accordance with yet other embodiments of the disclosure, a memory device has a stack structure and a base structure vertically below the stack structure. The stack structure includes blocks extending in parallel in a first horizontal direction. The blocks individually include tiers. Each tier has conductive material and insulative material vertically neighboring the conductive material. The blocks individually comprise an at least partially filled slot and vertically extending strings of memory cells. The at least partially filled slot vertically extends through the tiers. The at least partially filled slot has a backbone region and rib regions. The backbone region substantially linearly extends in the first horizontal direction. The rib regions intersect the backbone region. The rib regions individually substantially linearly extend in at least one second horizontal direction angled relative to the first horizontal direction. The vertically extending strings of memory cells are within horizontal areas of the rib regions of the least partially filled slot. The base structure includes plug structures and laterally extending conductive structures. The plug structures are in electrical communication with the vertically extending strings of memory cells. The laterally extending conductive structures contact sidewalls of the plug structures.

FIG. 3 is a simplified, partial top-down view of the microelectronic device structure 100 following the processing stage described with reference to FIGS. 2R and 2Q. As depicted in FIG. 2R, the microelectronic device structure 100 includes the vertical memory string structures 272 positioned within the rib regions 110 of the profile slot 106, wherein the vertical memory string structures 272 are horizontally adjacent to sidewalls of the stack structure 210 partially defining the rib regions 110. Also shown in FIG. 3 are the top plugs 286 and the bottom plugs 246 vertically offset from (e.g., vertically above and vertically below, respectively) and in electrical communication with the vertical memory string structures 272.

As also shown in FIG. 3, the microelectronic device structure 100 includes filled trench structures 302 formed by filling the trenches 276 (FIG. 2Q) in the stack structure 210 (FIG. 2Q) in the microelectronic device structure 100 with dielectric material (e.g., dielectric oxide material, such as silicon oxide). The filled trench structures 302 may horizontally extend (e.g., in the X-direction) substantially parallel to the backbone region 108 of the profile slot 106. Additionally, the filled trench structure 302 may have a horizontal length (e.g., in the X-direction) substantially equivalent to the horizontal length (e.g., in the X-direction) of the backbone region 108 of the profile slot 106.

As shown in FIG. 3, each rib region 110 of the profile slot 106 is horizontally interposed (e.g., in the X-direction) between two horizontally neighboring portions of the stack structure 210. The horizontal dimensions of individual rib regions 110 of the profile slot 106 may be selected to facilitate sufficient structural stability of the stack structure 210 so as to substantially maintain its shape and configuration during the processing stages previously described herein with reference to FIG. 1 and FIGS. 2A through 2R. Configurations of portions of the preliminary stack structure 102 (FIG. 2P) and the stack structure 210 (FIG. 2R) between individual rib regions 110 may impede (e.g., substantially prevent) collapse of portions of the preliminary stack structure 102 (FIG. 2P) and the stack structure 210 (FIG. 2R).

As set forth above with respect to FIGS. 2J through 2O, trim-etch cycles may begin at ends of individual rib regions 110 nearest the backbone region 108 of the profile slot 106 and may progress away from the backbone region 108 of the profile slot 106. FIG. 3 depicts general horizontal directions 304 (e.g., extending away from opposing sides of the backbone region 108) that subsequent trim-etch cycles may follow.

The stack structure 210 of the microelectronic device structure 100 may be divided (e.g., segmented, partitioned) into blocks 306 separated from one another (e.g., in the Y-direction) by the filled trench structures 302. Alternatively, the stack structure 210 of the microelectronic device structure 100 may be divided into blocks electrically separated from one another by the filled trench structures 302 and the backbone region 108 (e.g., the size of the blocks are approximately one-half of the size of the block 306 as shown in FIG. 3). The filled trench structures 302 may individually vertically extend (e.g., in the Z-direction) completely through the stack structure 210.

At least some of the blocks 306 of the stack structure 210 may horizontally extend substantially in parallel in the X-direction. Each of the blocks 306 of the stack structure 210 may exhibit substantially the same geometric configuration (e.g., substantially the same dimensions and substantially the same shape) as each other of the block 306, or one or more of the blocks 306 may exhibit a different geometric configuration (e.g., one or more different dimensions and/or a different shape) than one or more other of the blocks 306. In addition, each pair of horizontally neighboring blocks 306 of the stack structure 210 may be horizontally separated from one another by substantially the same distance (e.g., corresponding to a width in the Y-direction of individual filled trench structure 302) as each other pair of horizontally neighboring blocks 306 of the stack structure 210, or at least one pair of horizontally neighboring blocks 306 of the stack structure 210 may be horizontally separated from one another by a different distance than that separating at least one other pair of horizontally neighboring blocks 306 of the stack structure 210. In some embodiments, the blocks 306 of the preliminary stack structure 102 are substantially uniformly (e.g., substantially non-variably, substantially equally, substantially consistently) sized, shaped, and spaced relative to one another.

The block 306 may be further subdivided into sub-blocks 308, an individual sub-block 308 being defined by the horizontal profile of a corresponding rib region 110. Thus, a sub-block 308 may include the vertical memory string structures 272 on two (2) opposing sidewalls 208 of the stack structure 210 partially defined by an individual rib region 110 in the stack structure 210.

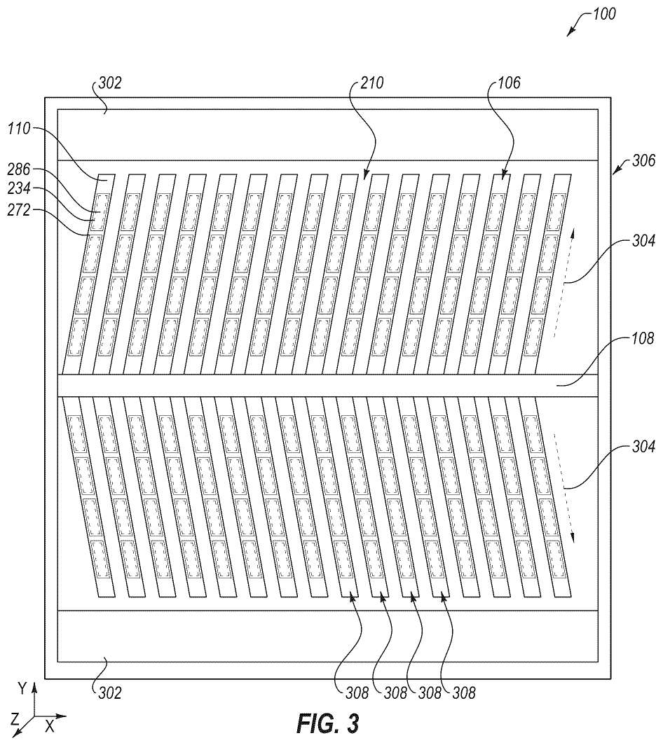

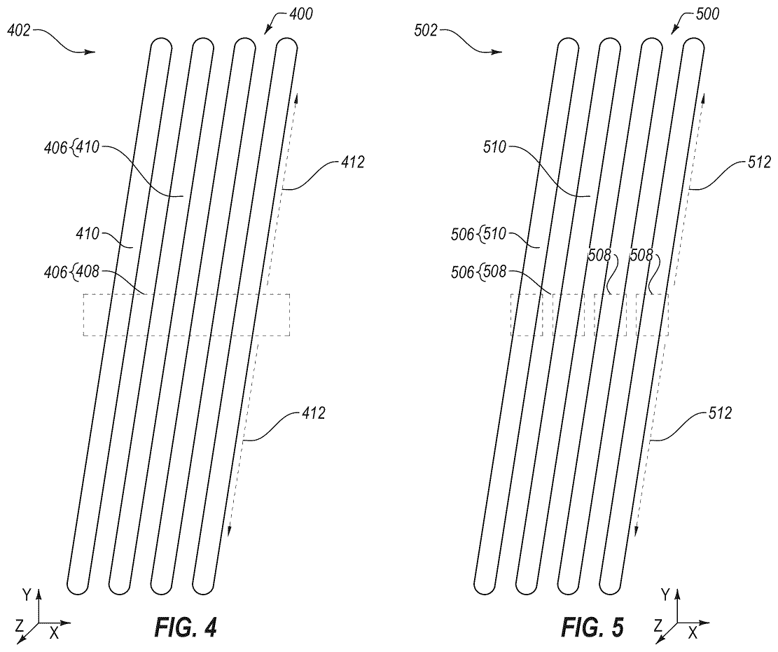

While FIGS. 1, 2A through 2R, and 3 depict a configuration of the profile slot 106 according to embodiments of the disclosure, in additional embodiments the microelectronic device structure 100 may be formed to have a different profile slot configuration. Non-limiting examples of such different profile slot configurations are described in further detail below with reference to FIGS. 4 through 7. As shown in FIGS. 4 through 8, microelectronic device structures 400, 500, 600, 700, 800 may be formed to have profile slots 406, 506, 606, 706, 806, respectively, each of which has a different horizontal profile (e.g., as viewed from a top-down perspective) than that of the profile slot 106 of the microelectronic device structure 100. While the microelectronic device structures 400, 500, 600, 700, 800 may respectively have different profile slots 406, 506, 606, 706, 806 and the microelectronic device structures 400, 500, 600, 700, 800 may be subject to processing stages similar to those previously described with reference to FIGS. 2A through 2R to form a desirable microelectronic devices of the disclosure.

Referring to FIG. 4, a preliminary stack structure 402 (e.g., corresponding to the preliminary stack structure 102 (FIGS. 1 and 2A through 2P)) may be formed to have a profile slot 406 including a first region 408 extending in a first horizontal direction (e.g., the X-direction), and second regions 410 intersecting the first region 408 and extending in parallel in a second horizontal direction angled relative to the first horizontal direction. The first region 408 may have a function similar to that of the backbone region 108 of the profile slot 106 previously described with reference to FIGS. 1, 2A through 2R, and 3; and may exhibit a single, elongate horizontal cross-sectional shape (e.g., a rectangular horizontal cross-sectional shape). The second regions 410 may have functions similar to those of the rib regions 110 of the profile slot 106 previously described with reference to FIGS. 1, 2A through 2R, and 3, and may individually exhibit a single, elongate horizontal cross-sectional shape (e.g., a rectangular horizontal cross-sectional shape) that partially horizontally overlaps the first region 408.

To form the profile slot 406, the second regions 410 may be formed in the preliminary stack structure 402 (e.g., through a material removal process, such as an etching process), and then the first region 408 may be formed in the preliminary stack structure 402 (e.g., through an additional material removal process, such as an additional etching process). The first region 408 may be formed after (e.g., subsequent to) the formation of the second regions 410. Following the formation of the profile slot 406, the microelectronic device structure 400 may be subjected to additional processing substantially similar to that previously described with reference to FIGS. 2A through 2R for the microelectronic device structure 100. Subsequent trim-etch cycles (e.g., similar to those previously described with reference to FIGS. 2J through 2O) employed during the additional processing may follow general horizontal directions 412 away from the first region 408.

Referring to FIG. 5, a preliminary stack structure 502 (e.g., corresponding to the preliminary stack structure 102 (FIGS. 1 and 2A through 2P)) may be formed to have multiple profile slots 506 individually including a first region 508, and a second region 510 intersecting the first region 508. The first regions 508 of the multiple profile slots 506 may be discrete from one another, may form a row of the first regions 508 extending in a first horizontal direction (e.g., the X-direction), and may be substantially aligned with one another in a second horizontal direction (e.g., the Y-direction) orthogonal to the first horizontal direction. The second regions 510 of the multiple profile slots 506 may be discrete from one another, and may extend in parallel in a third horizontal direction angled relative to the first horizontal direction and the second horizontal direction. The first region 508 of an individual profile slot 506 may have a function similar to that of the backbone region 108 of the profile slot 106 previously described with reference to FIGS. 1, 2A through 2R, and 3; and may exhibit a desired horizontal cross-sectional shape (e.g., a rectangular horizontal cross-sectional shape, a square horizontal cross-sectional shape, a circular horizontal cross-sectional shape). The second region 510 of an individual profile slot 506 may have a function similar to that of the rib regions 110 of the profile slot 106 previously described with reference to FIGS. 1, 2A through 2R, and 3, and may exhibit a single, elongate horizontal cross-sectional shape (e.g., a rectangular horizontal cross-sectional shape) that partially horizontally overlaps the first region 508.

To form the profile slots 506, the second regions 510 may be formed in the preliminary stack structure 502 (e.g., through a material removal process, such as an etching process), and then the first regions 508 may be formed in the preliminary stack structure 502 (e.g., through an additional material removal process, such as an additional etching process). The first regions 508 may be formed after (e.g., subsequent to) the formation of the second regions 510. Following the formation of the profile slots 506, the microelectronic device structure 500 may be subjected to additional processing substantially similar to that previously described with reference to FIGS. 2A through 2R for the microelectronic device structure 100. Subsequent trim-etch cycles (e.g., similar to those previously described with reference to FIGS. 2J through 2O) employed during the additional processing may follow general horizontal directions 512 away from respective first regions 508.

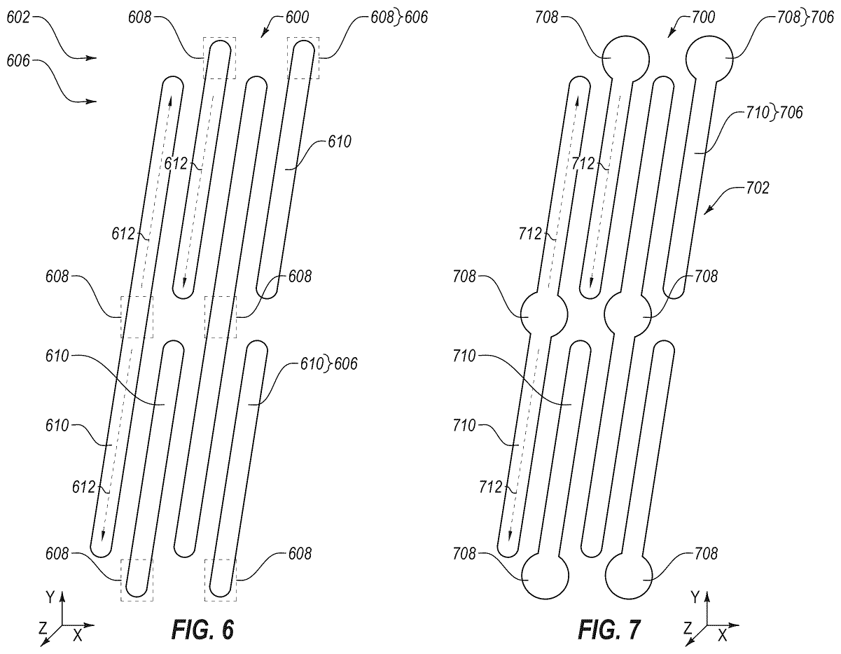

Referring to FIG. 6, a preliminary stack structure 602 (e.g., corresponding to the preliminary stack structure 102 (FIGS. 1 and 2A through 2P)) may be formed to have multiple profile slots 606 individually including a first region 608, and a second region 610 intersecting the first region 608. The first regions 608 of the multiple profile slots 606 may be discrete from one another, and may form multiple rows of the first regions 608 individually extending in a first horizontal direction (e.g., the X-direction). First regions 608 within an individual row may be substantially aligned with one another in a second horizontal direction (e.g., the Y-direction) orthogonal to the first horizontal direction. First regions 608 within different rows that one another may be horizontally offset from one another in the second horizontal direction. The second regions 610 of the multiple profile slots 606 may be discrete from one another, and may extend in parallel in a third horizontal direction angled relative to the first horizontal direction and the second horizontal direction. Profile slots 606 neighboring one another in the first horizontal direction may be partially offset from one another in the third horizontal direction. For example, the second regions 610 of two (2) of the profile slots 606 neighboring one another in the first horizontal direction may partially overlap one another in the third horizontal direction; and the first regions 608 of the two (2) of the profile slots 606 may be completely offset from one another in the third horizontal direction. As shown in FIG. 6, some of the profile slots 606 may be substantially aligned with one another in the third horizontal direction, such that the some of the profile slots 606 extend in series with one another in the third horizontal direction. Portions of the preliminary stack structure 602 intervene between the some of the profile slots 606 substantially aligned with one another in the third horizontal direction.

The first region 608 of an individual profile slot 606 may have a function similar to that of the backbone region 108 of the profile slot 106 previously described with reference to FIGS. 1, 2A through 2R, and 3; and may exhibit a desired horizontal cross-sectional shape (e.g., a rectangular horizontal cross-sectional shape, a square horizontal cross-sectional shape, a circular horizontal cross-sectional shape). The second region 610 of an individual profile slot 606 may have a function similar to that of the rib regions 110 of the profile slot 106 previously described with reference to FIGS. 1, 2A through 2R, and 3, and may exhibit a single, elongate horizontal cross-sectional shape (e.g., a rectangular horizontal cross-sectional shape) that partially horizontally overlaps the first region 608.

To form the profile slots 606, the second regions 610 may be formed in the preliminary stack structure 602 (e.g., through a material removal process, such as an etching process), and then the first regions 608 may be formed in the preliminary stack structure 602 (e.g., through an additional material removal process, such as an additional etching process). The first regions 608 may be formed after (e.g., subsequent to) the formation of the second regions 610. Following the formation of the profile slots 606, the microelectronic device structure 600 may be subjected to additional processing substantially similar to that previously described with reference to FIGS. 2A through 2R for the microelectronic device structure 100. Subsequent trim-etch cycles (e.g., similar to those previously described with reference to FIGS. 2J through 2O) employed during the additional processing may follow general horizontal directions 612 away from respective first regions 608.

Referring to FIG. 7, a preliminary stack structure 702 (e.g., corresponding to the preliminary stack structure 102 (FIGS. 1 and 2A through 2P)) may be formed to have multiple profile slots 706 individually including a first region 708, and a second region 710 intersecting the first region 708. The first regions 708 of the multiple profile slots 706 may be discrete from one another, and may form multiple rows of the first regions 708 individually extending in a first horizontal direction (e.g., the X-direction). First regions 708 within an individual row may be substantially aligned with one another in a second horizontal direction (e.g., the Y-direction) orthogonal to the first horizontal direction. First regions 708 within different rows that one another may be horizontally offset from one another in the second horizontal direction. The second regions 710 of the multiple profile slots 706 may be discrete from one another, and may extend in parallel in a third horizontal direction angled relative to the first horizontal direction and the second horizontal direction. Profile slots 706 neighboring one another in the first horizontal direction may be partially offset from one another in the third horizontal direction. For example, the second regions 710 of two (2) of the profile slots 706 neighboring one another in the first horizontal direction may partially overlap one another in the third horizontal direction; and the first regions 708 of the two (2) of the profile slots 706 may be completely offset from one another in the third horizontal direction. As shown in FIG. 7, some of the profile slots 706 may be substantially aligned with one another in the third horizontal direction, such that the some of the profile slots 706 extend in series with one another in the third horizontal direction. Portions of the preliminary stack structure 702 intervene between the some of the profile slots 706 substantially aligned with one another in the third horizontal direction.

The first region 708 of an individual profile slot 706 may have a function similar to that of the backbone region 108 of the profile slot 106 previously described with reference to FIGS. 1, 2A through 2R, and 3; and may exhibit a desired horizontal cross-sectional shape (e.g., a rectangular horizontal cross-sectional shape, a square horizontal cross-sectional shape, a circular horizontal cross-sectional shape). The second region 710 of an individual profile slot 706 may have a function similar to that of the rib regions 110 of the profile slot 106 previously described with reference to FIGS. 1, 2A through 2R, and 3, and may exhibit a single, elongate horizontal cross-sectional shape (e.g., a rectangular horizontal cross-sectional shape) that partially horizontally overlaps the first region 708.

To form the profile slots 706, the first regions 608 and the second regions 610 thereof may be formed in the preliminary stack structure 602 at substantially the same time (e.g., substantially simultaneously). Following the formation of the profile slots 706, the microelectronic device structure 700 may be subjected to additional processing substantially similar to that previously described with reference to FIGS. 2A through 2R for the microelectronic device structure 100. Subsequent trim-etch cycles (e.g., similar to those previously described with reference to FIGS. 2J through 2O) employed during the additional processing may follow general horizontal directions 712 away from respective first regions 708.

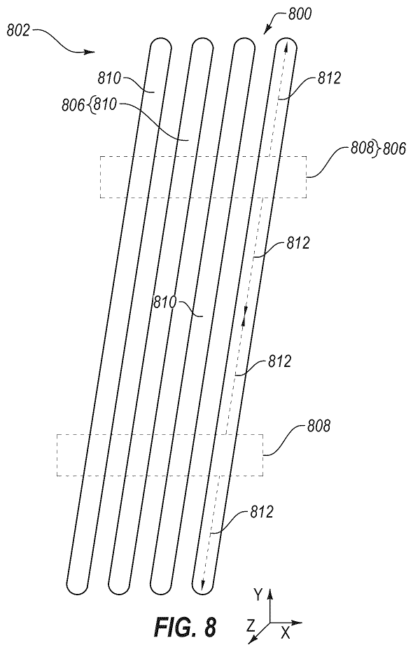

Referring to FIG. 8, a preliminary stack structure 802 (e.g., corresponding to the preliminary stack structure 102 (FIGS. 1 and 2A through 2P)) may be formed to have a profile slot 806 including multiple first regions 808 extending in parallel a first horizontal direction (e.g., the X-direction) and offset from one another in a second horizontal direction (e.g., the Y-direction) orthogonal to the first horizontal direction; and multiple second regions 810 intersecting the first regions 808 and extending in parallel in a third horizontal direction angled relative to the first horizontal direction and the second horizontal direction. The first regions 808 may individually be offset from a midpoint of the profile slot 806 in the third horizontal direction. For example, two (2) the first regions 808 may be positioned an approximate quarter-length position and an approximate three-quarters-length position, respectively, along the profile slot 806 in the third horizontal direction. The first regions 808 of the profile slot 806 may individually have a function similar to that of the backbone region 108 of the profile slot 106 previously described with reference to FIGS. 1, 2A through 2R, and 3; and may individually exhibit an elongate horizontal cross-sectional shape (e.g., a rectangular horizontal cross-sectional shape). The second regions 810 of the profile slot 806 may have functions similar to those of the rib regions 110 of the profile slot 106 previously described with reference to FIGS. 1, 2A through 2R, and 3, and may individually exhibit a elongate horizontal cross-sectional shape (e.g., a rectangular horizontal cross-sectional shape) that horizontally overlaps each of the first regions 808.

To form the profile slot 806, the second regions 810 may be formed in the preliminary stack structure 802 (e.g., through a material removal process, such as an etching process), and then the first regions 808 may be formed in the preliminary stack structure 802 (e.g., through an additional material removal process, such as an additional etching process). The first regions 808 may be formed after (e.g., subsequent to) the formation of the second regions 810. In additional embodiments, the first regions 808 and the second regions 810 are formed substantially simultaneously with one another to form the profile slot 806. Following the formation of the profile slot 806, the microelectronic device structure 800 may be subjected to additional processing substantially similar to that previously described with reference to FIGS. 2A through 2R for the microelectronic device structure 100. Subsequent trim-etch cycles (e.g., similar to those previously described with reference to FIGS. 2J through 2O) employed during the additional processing may follow general horizontal directions 812 away from respective first regions 808.

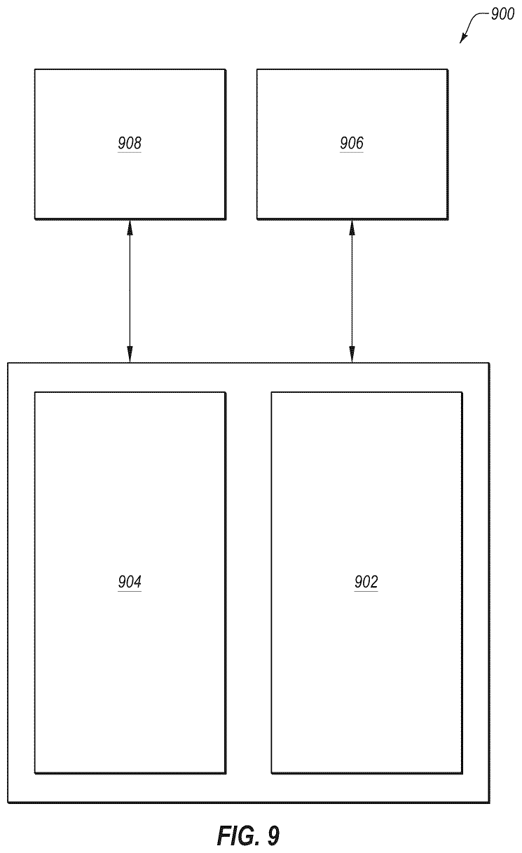

Microelectronic devices structures (e.g., the microelectronic device structure 100, 400, 500, 600, 700, 800 previously described with reference to one or more of FIGS. 1 through 8) in accordance with embodiments of the disclosure may be used in embodiments of electronic systems of the disclosure. For example, FIG. 9 is a block diagram of an illustrative electronic system 900 according to embodiments of this disclosure. The electronic system 900 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® tablet, a SURFACE® tablet, an electronic book, a navigation device.

The electronic system 900 includes at least one memory device 902. The memory device 902 may comprise, for example, a microelectronic device structure previously described herein (e.g., the microelectronic device structure 100, 400, 500, 600, 700, 800 previously described with reference to one or more of FIGS. 1 through 8). The electronic system 900 may further include at least one electronic signal processor device 904 (often referred to as a “microprocessor”). The electronic signal processor device 904 may, optionally, include a microelectronic device structure previously described herein (e.g., the microelectronic device structure 100, 400, 500, 600, 700, 800 previously described with reference to one or more of FIGS. 1 through 8). While the memory device 902 and the electronic signal processor device 904 are depicted as two (2) separate devices in FIG. 9, in additional embodiments, a single (e.g., only one) memory/processor device having the functionalities of the memory device 902 and the electronic signal processor device 904 may be included in the electronic system 900. In such embodiments, the memory/processor device may include a microelectronic device structure previously described herein (e.g., the microelectronic device structure 100, 400, 500, 600, 700, 800 previously described with reference to one or more of FIGS. 1 through 8). The electronic system 900 may further include one or more input devices 906 for inputting information into the electronic system 900 by a user, such as, for example, a mouse or other pointing device, a keyboard, a touchpad, a button, or a control panel. The electronic system 900 may further include one or more output devices 908 for outputting information (e.g., visual or audio output) to a user such as, for example, a monitor, a display, a printer, an audio output jack, a speaker, etc. In some embodiments, the input device 906 and the output device 908 comprise a single touchscreen device that can be used both to input information to the electronic system 900 and to output visual information to a user. The input device 906 and the output device 908 may communicate electrically with one or more of the memory device 902 and the electronic signal processor device 904.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A method of forming a microelectronic device, comprising:
forming a preliminary stack structure over a base structure, the preliminary stack structure comprising tiers each comprising a first material and an insulative material vertically neighboring the first material;
forming a slot vertically extending through the preliminary stack structure and comprising:
a first region horizontally extending in a first direction; and
second regions intersecting the first region and horizontally extending in at least one second direction angled relative to the first direction;
forming memory cell material within the slot;
forming mask material within the slot and over the memory cell material;
forming trim material within the slot and over the mask material;
removing portions of the trim material within the first region of the slot; and
removing portions of the trim material, the mask material, and the memory cell material within the second regions of the slot to form memory string structures vertically extending through the preliminary stack structure and horizontally separated from one another in the at least one second direction.

2. The method of claim 1, wherein removing portions of the trim material, the mask material, and the memory cell material within the second regions of the slot comprises performing trim-etch cycles individually comprising:
removing portions of the trim material within the second regions of the slot to expose portions of the mask material within the second regions of the slot;
forming an inhibition material from the portions of the mask material within the second regions of the slot;
removing additional portions of the trim material adjacent to the inhibition material to expose additional portions of the mask material within the second regions of the slot; and
removing the additional portions of the mask material.

3. The method of claim 2, further comprising, after completing the trim-etch cycles, partially removing portions of the memory cell material horizontally overlapping recesses resulting from removing the additional portions of the mask material.

4. The method of claim 3, wherein partially removing portions of the memory cell material comprises:
selectively etching portions of semiconductor material of the memory cell material to expose portions of oxide material of the memory cell material;
selectively etching the exposed portions of the oxide material of the memory cell material to expose portions of nitride material of the memory cell material; and
selectively etching the exposed portions of the nitride material of the memory cell material to expose portions of additional oxide material of the memory cell material.

5. The method of claim 4, further comprising:
forming dielectric liner material within the slot and over the memory cell material prior to forming the mask material; and
removing portions of the dielectric liner material exposed by removing the additional portions of the mask material prior to selectively etching the portions of the semiconductor material of the memory cell material.

6. The method of claim 1, the first material of the tiers of the preliminary stack structure comprising a sacrificial material, the method further comprising replacing the sacrificial material of the tiers with conductive material after forming the memory string structures.

7. The method of claim 1, further comprising:
forming plug openings within horizontal areas of the second regions of the slot and vertically extending into the base structure; and
filling the plug openings with the memory cell material prior to forming the mask material within the slot, portions of the memory cell material within the slot continuous with additional portions of the memory cell material within the plug openings.

8. The method of claim 7, further comprising:
forming the base structure to comprise sacrificial material vertically interposed between semiconductor material and additional semiconductor material; and
forming the additional portions of the memory cell material in contact with the sacrificial material of the base structure.

9. The method of claim 8, further comprising:
forming additional slots vertically extending through the preliminary stack structure and into the base structure, the additional slots exposing side surfaces of the sacrificial material of the base structure;
at least partially removing the sacrificial material of the base structure after forming the additional slots to form recesses partially exposing the additional portions of the memory cell material filling the plug openings;
after forming the recesses, laterally extending the recesses into the additional portions of the memory cell material to expose semiconductor material of the additional portions of the memory cell material; and
filling the laterally extended recesses with conductively doped semiconductor material.

10. The method of claim 1, further comprising, prior to removing the portions of the trim material within the first region of the slot:
filling remaining portions of the first region of the slot with a sacrificial fill material after forming the trim material within the slot;
forming additional mask material to substantially continuously horizontally extend over and cover horizontal areas of the preliminary stack structure and the slot;
forming an opening vertically extending completely through the additional mask material and confined within horizontal boundaries of the first region of the slot; and
selectively exhuming the sacrificial fill material by way of the opening in the additional mask material.

11. The method of claim 1, further comprising selecting the memory cell material to comprise:
first dielectric oxide material substantially covering sidewalls of the preliminary stack structure;
dielectric nitride material substantially covering the first dielectric oxide material;
second dielectric oxide material substantially covering the dielectric nitride material; and
semiconductor material extending substantially covering the second dielectric oxide material.

12. The method of claim 1, further comprising:
selecting the mask material to comprise polysilicon; and
selecting the trim material to comprise silicon nitride.

13. A microelectronic device, comprising:
a stack structure comprising tiers each including conductive material vertically neighboring insulative material, the stack structure divided into blocks horizontally extending in parallel in a first direction and separated from one another in a second direction orthogonal to the first direction by insulative slot structures, at least one of the blocks comprising:
a slot vertically extending through all of the tiers and comprising:
a first region horizontally extending in the first direction; and
second regions intersecting the first region and horizontally extending in at least one third direction angled relative to the first direction and the second direction; and
memory string structures vertically extending through the stack structure and within horizontal areas of the second regions of the slot, the memory string structures horizontally separated from one another in the at least one third direction.

14. The microelectronic device of claim 13, wherein the memory string structures each comprise:
a volume of a first dielectric oxide material on a sidewall of the stack structure partially defining the slot;
a volume of a dielectric nitride material on the volume of the first dielectric oxide material;
a volume of a second dielectric oxide material on the volume of the dielectric nitride material; and
a volume of semiconductor material on the volume of the second dielectric oxide material.

15. The microelectronic device of claim 14, further comprising a base structure vertically underlying the stack structure and comprising:
source contact structures within the horizontal areas of the second regions of the slot of the at least one of the blocks and contacting the memory string structures of the at least one of the blocks; and
additional conductive material contacting side surfaces of the source contact structures.

16. The microelectronic device of claim 15, wherein the source contact structures individually comprise:
an additional volume of the first dielectric oxide material;
an additional volume of the dielectric nitride material on the additional volume of the first dielectric oxide material;
an additional volume of the second dielectric oxide material the additional volume of the dielectric nitride material; and
an additional volume of the semiconductor material on the additional volume of the second dielectric oxide material, the additional volume of the semiconductor material continuous with the volume of the semiconductor material of each of the memory string structures.

17. The microelectronic device of claim 16, wherein the additional conductive material of the base structure directly physically contacts the additional volume of the semiconductor material of each of the source contact structures.

18. The microelectronic device of claim 17, wherein each of the source contact structures horizontally overlaps and contacts multiple of the memory string structures.

19. The microelectronic device of claim 13, further comprising drain contact structures within the horizontal areas of the second regions of the slot and contacting the memory string structures, the drain contact structures vertically overlying and horizontally overlapping the source contact structures.

20. A memory device, comprising:
a stack structure comprising:
blocks extending in parallel in a first horizontal direction and individually including tiers each comprising conductive material and insulative material vertically neighboring the conductive material, the blocks individually comprising:
an at least partially filled slot vertically extending through the tiers and comprising:
a backbone region substantially linearly extending in the first horizontal direction; and
rib regions intersecting the backbone region and individually substantially linearly extending in at least one second horizontal direction angled relative to the first horizontal direction;
vertically extending strings of memory cells within horizontal areas of the rib regions of the at least partially filled slot; and
a base structure vertically below the stack structure and comprising:
source contact structures in electrical communication with the vertically extending strings of memory cells; and
laterally extending conductive structures contacting sidewalls of the source contact structures.
